(19) United States
(12) Patent Application Publication
(10) Pub. No.: US 2024/0049588 A1
(43) Pub. Date: Feb. 8, 2024

(54) ORGANIC INFRARED PHOTODETECTION DEVICES UTILIZING AN INSULATIVE COMPONENT WITHIN THE ACTIVE LAYER

(71) Applicants: Jason D. Azoulay, Atlanta, GA (US); Jasmine Lim, Rosemead, CA (US); Naresh Eedugurala, Hattiesburg, MS (US)

(72) Inventors: Jason D. Azoulay, Atlanta, GA (US); Jasmine Lim, Rosemead, CA (US); Naresh Eedugurala, Hattiesburg, MS (US)

(21) Appl. No.: 18/363,319

(22) Filed: Aug. 1, 2023

Related U.S. Application Data
(60) Provisional application No. 63/370,013, filed on Aug. 1, 2022.

(51) Int. Cl. H10K 85/10; C08G 61/12; H10K 30/30

(52) U.S. Cl. CPC H10K 85/113; C08G 61/126; H10K 85/151; H10K 30/30; C08G 2261/94; C08G 2261/124; C08G 2261/1412; C08G 2261/148; C08G 2261/18; C08G 2261/228; C08G 2261/3243; C08G 2261/3223

(57) ABSTRACT

The present invention relates to a photodetector and methods for making a photodetector configured for converting light to an electronic signal. The photodetector includes a substrate containing a hole transport component and electron transport component; one or more photoactive layers including one or more semiconducting materials that comprise a photoactive small molecule, oligomeric, or polymeric electron donor and an electron acceptor, wherein the electron donor has a narrow bandgap of less than 1.4 eV; and one or more insulating materials, wherein the one or more semiconducting materials and the one or more insulating materials are present in a weight ratio of 1:0.1 to about 1:100; a cathode in electrical contact with the electron or hole transport component; and an anode in electrical contact with the hole or electron transport component.

### CROSS REFERENCE TO RELATED APPLICATIONS

This application claims the benefit of U.S. Provisional Application No. 63/370,013, filed on Aug. 1, 2022, the entire disclosure of which is hereby incorporated by reference as if set forth fully herein.

### STATEMENT OF GOVERNMENT SUPPORT

This invention was made with government support under grant/contract OIA—1757220 awarded by the National Science Foundation. The Government has certain rights in the invention.

### FIELD OF THE INVENTION

The present invention relates to the field of organic electronics, specifically organic photoresponsive devices. Further, the invention is directed to devices for sensitive detection of infrared light using an active layer adapted for reducing device noise current. The active layer includes a light sensitive material and an insulative component that modifies the output signal of the device.

### BACKGROUND OF THE INVENTION

The last two decades have witnessed the rise of soft condensed matter systems in the form of solution-processed organic semiconductors (OSCs) based on molecules and polymers. These materials have enabled a new generation of optoelectronic technologies owing to their synthetic modularity, distinct manufacturing paradigms, rich variety of optical and transport phenomena, and opportunities for modification of device structures that were not possible with inorganic materials.¹⁻¹⁴ OSCs that effectively produce and harvest visible and near-IR light find utility in a variety of commercially relevant optoelectronic technologies such as the production of organic light-emitting diodes (OLEDs), organic photovoltaics (OPVs), and organic field-effect transistors (OFETs).

The progression of organic materials into the infrared spectrum has encountered high dark current and noise due to increased thermally generated carriers.¹⁵ Noise is further amplified under the application of an external reverse bias, the normal operating mode of an organic photodetector or organic photodiodes (OPD). These issues remain challenging for enabling OPDs with high detectivity and low noise.

Photodetectors operating across the near infrared-shortwave infrared (NIR-SWIR, ═=0.9-1.8) are essential elements in modern scientific, industrial, energy, medical, semiconductor, and defense applications. Emerging technologies for NIR-SWIR photodetection are having a global societal impact in renewable energy, healthcare, information science, building and machine automation. However, these technologies are subject to stringent cooling requirements, high-costs, and are largely incompatible with silicon-based technologies, attributes that are prohibitive for many applications and emerging technologies.¹⁶⁻¹⁹ Despite widespread efforts in scientific and engineering disciplines, photodetection beyond the cut-off wavelength of silicon (λ_{c}˜1.1/1.0 μm) remains dependent on archetypal crystalline inorganic semiconductors such as germanium (Ge) or alloys of indium gallium arsenide (InGaAs).

These present-day photodetection devices rely primarily on semiconductors that, depending on their bandgap, are able to transduce photons of different energies into electrical signals for subsequent processing, image reconstruction and storage. Historically, this has been enabled by the use of photodiodes and phototransistors made from crystalline inorganic semiconductors such as silicon or Group III-V compounds—materials heavily used in modern electronics and optoelectronics. Infrared photon detection/sensing is currently dominated by indium antimonide (InSb), which covers the shortwave infrared (SWIR, λ=1-3 μm) and midwave infrared (MWIR, λ=3-5 μm) regions, and alloys of mercury-cadmium-telluride (MCT HgCdTe) for the longwave infrared (LWIR, λ=18-14 μm) region. These materials are fabricated from single crystals/epitaxial growth and suffer from limited modularity, intrinsic fragility, high-power consumption, requiring cryogenic cooling/low temperature operation, and are largely incompatible with integrated circuit technologies. They are very expensive and cannot be fabricated into large formats. Emerging technologies require significant cost reductions, form-factors, and mechanical properties that can provide pathways to embodiments and performance attributes that are not available from epitaxy-based/single-crystal technologies. For example, the cost of sensitive and fast image sensors is prohibitive for emerging applications.

A constraining feature of these narrow bandgap material systems is the high noise current density under an applied bias, resulting in specific detectivities (D*) under practical operating conditions that are too low for practical utilization. In contrast, organic photodiodes (OPDs) comprised of π-conjugated organic semiconductors (OSCs) overcome critical manufacturing and operating drawbacks of these inorganic semiconductors. Bulk-heterojunction (BHJ) active layers blend n-type and p-type materials, which provide significant advantages including low-costs, no cooling requirement, diverse production processes which are resource-friendly and energy-efficient, scalability, seamless complementary metal-oxide-semiconductor (CMOS) integration, tolerance toward structural defects and disorder and form factors (e.g., shapes and sizes) that are not realizable using crystalline photodiodes. These attributes, combined with flexibility in materials and device design, provide opportunities not available with inorganics, and contrast with the extreme levels of order, high temperatures, and strict growth requirements of conventional IR semiconductors.

State-of-the-art polymer photodetectors/OPDs largely operate in the visible to near-infrared (λ=0.4-1 μm, VIS-NIR) region. Current efforts in materials design and synthesis have developed OSCs with narrow bandgaps capable of optical to electrical transduction of longer-wavelength light. A property that allows a comparison of performance between different detector technologies is the specific detectivity (D*). Values for D* of 10¹² Jones (cm·Hz^{1/2} W⁻¹) or larger have been reported for OPDs operating in the visible region, similar to their Si-based counterparts. In contrast, D* is several orders of magnitude lower for NIR-SWIR OPDs. Furthermore, while D* values ranging from ˜10¹¹-10¹² Jones have been reported at 0 V within a spectral range of 0.6 μm-1.4 μm, these measurements do not always account for all contributions to the noise. Furthermore, OPDs usually operate in reverse bias, where the measured reverse dark current (J_{dark}) rises significantly from the value at 0 V. This results in a higher noise current density, resulting in D* values under practical operating conditions of about 10⁸ Jones, far too low for practical utilization, meaning that inorganic semiconductor devices are the only viable technology for sensitively detecting faint NIR-SWIR light.

Thus, despite the increasing availability of organic IR materials, a major challenge facing IR-OPDs is higher dark current and noise as a consequence of decreasing bandgaps, due to higher rates of charge carrier recombination, trap states, and thermal population of free carriers.^{5,6} Consequently, dark current suppression in OPDs has been the subject of several reports in the literature, with the most frequently utilized approaches encompassing injection blocking/charge selective layers, improved contact alignment, manipulation of blend morphology and device geometry, prevention of shunt paths via layer thickness increase, and charge transport layer structuring.^{22, 23} In the context of molecular design, a decrease in noise can be realized from tuning the effective bandgap (energetic alignments) and the degree of electronic disorder in the BHJ devices through molecular design. However, this requires extensive control of molecular structure that is difficult to achieve in narrow bandgap material systems.

U.S. Pat. No. 9,236,574 B2 relates to dinaphthol [2,3-a:2′,3′-h]phenazine compounds, methods for their preparation and intermediates used therein, formulations comprising them, the use of these compounds and formulations useful as semiconductor materials in organic electronic (OE) devices, and OE devices comprising these compounds and formulations.

U.S. Publication No. 2018/0261768 relates to compositions comprising an organic semiconducting material, a solvent, and specifically selected polymer particles, which allow modification of the viscosity of such compositions. This publication also relates to the use of such compositions in the production of OE devices.

Shen et al., “Wettability Control of Interfaces for High-Performance Organic Thin-Film Transistors by Soluble Insulating Polymer Films”, ACS Publications,

https://pubs.acs.org/doi/10/1021/acsomega.0c00548, relates to the morphology, crystallization, and electrical properties of C₈-BTBT/PMMA blend films when different, soluble insulating polymer films were employed.

Macdec et al., “Organic Field Effect Transistors From Ambient Solution Processed Poly(Triarylamine)-Insulator Blends”, RCS Publications,

https://pubs.rsc.org/en/content/articlelanding/2008/jm/b802801j, relates to two component blends of amorphous poly(triarylamines) with selected amorphous and semi-crystalline polymeric binders for use in a semiconducting layer in organic field effect transistors.

### SUMMARY AND TERMS

The following sentences may be used to describe the invention:

1. In a first aspect, the present invention relates to a photodetector configured for converting light to an electronic signal, comprising:
a substrate comprising a hole transport component and an electron transport component;
one or more photoactive layers comprising:
   one or more semiconducting materials that comprise a photoactive small molecule, an oligomeric, or polymeric electron donor and an electron acceptor, wherein the electron donor has a narrow bandgap of less than 1.4 eV; and
   one or more insulating materials, wherein the one or more semiconducting materials and the one or more insulating materials are present in a weight ratio of 1:0.1 to about 1:100;
a cathode in electrical contact with the electron or hole transport component; and;
an anode in electrical contact with the hole or electron transport component.

2. In a second aspect, the present invention relates to a photodetector configured for converting light to an electronic signal, comprising:
a substrate comprising a hole transport component or an electron transport component;
one or more photoactive layers comprising:
   a heterojunction of two or more semiconducting materials that comprise a photoactive small molecule, oligomeric, or polymeric electron acceptor and an electron donor present in a weight ratio of from about 1:0.1 to about 1:100, wherein the electron donor has a narrow bandgap of less than 1.4 eV, and
   one or more insulating materials, wherein the two or more semiconducting materials and the one or more insulating materials are present in a weight ratio of 1:0.1 to about 1:100;
a cathode in electrical contact with the bulk heterojunction; and;
an anode in electrical contact with the bulk heterojunction.

3. The photodetector of any one of sentences 1-2, wherein the photoactive polymer electron donor may include a polymer according to Formula I or Formula II:

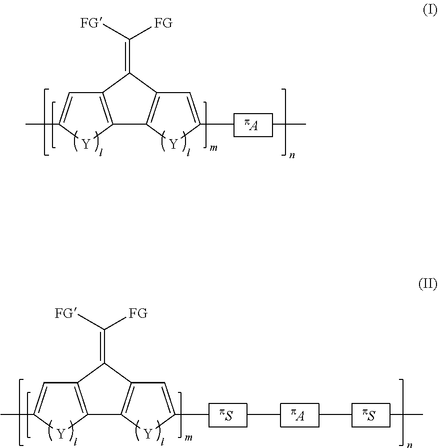

wherein FG and FG′ are each independently selected from the group consisting of hydrogen, an optionally substituted hydrocarbyl group containing 1 to 26 carbon atoms, or from about 5 to 26 carbon atoms, or from about 8 to about 16 carbon atoms, an optionally substituted aryl group containing 6 to 20 carbon atoms, or from about 6 to 16 carbon atoms, an optionally substituted heteroaryl group containing 3 to 26 carbon atoms, or from about 3 to 20 carbon atoms, or from about 3 to about 10 carbon atoms, and an optionally substituted aryl group containing 3 to 26 carbon atoms, or from about 3 to 20 carbon atoms, or from about 3 to about 10 carbon atoms,
the optionally substituted aryl group is selected from the group consisting of an arylene group substituted with an alkoxy group containing from 1 to 26 carbon atoms, an alkyl group containing from 1 to 26 carbon atoms, and an alkenyl group containing from 1 to 26 carbon atoms,
m is an integer of at least 1, and n is an integer of greater than 1;
Y is selected from the group consisting of S, BR⁵, PR⁵, Se, Te, NH, and Si,
R⁵ is a C₁-C₂₄ hydrocarbyl group;
Π_{S} is a conjugated spacer unit comprising a heteroarylene, wherein the heteroarylene contains 3 to 6 carbon atoms, or about 4 carbon atoms, and wherein the heteroatom of the heteroarylene is selected from the group consisting of S, O, Se, and N, or the heteroatom of the heteroarylene is S, or the heteroarylene according to the following structure:

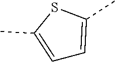

wherein π_{A} is an electron-poor or electron-deficient aromatic moiety that provides a structural unit in the copolymer according to formulae (A)-(F):

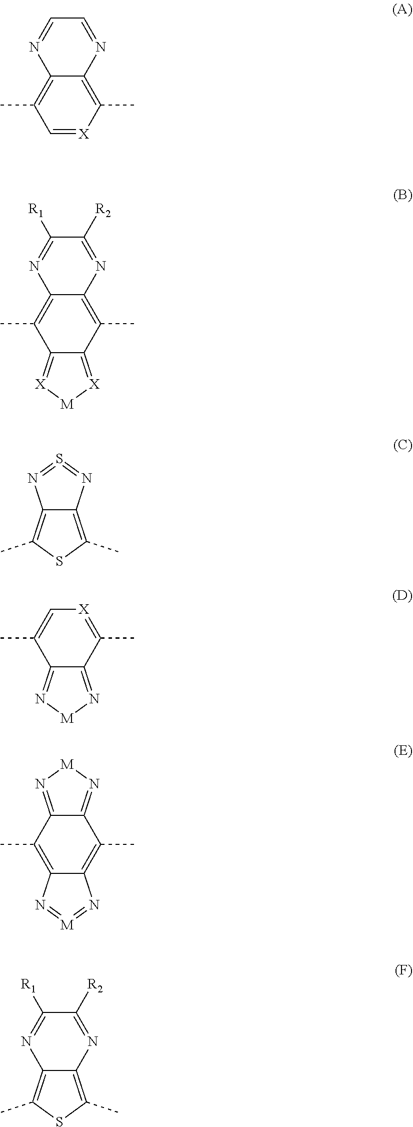

wherein R¹ and R² are each individually selected from a hydrogen, a hydrocarbyl group containing 1 to 26 carbon atoms, or from about 5 to 26 carbon atoms, or from about 8 to about 16 carbon atoms, an alkoxyl group containing 1 to 26 carbon atoms, or from about 5 to 26 carbon atoms, or from about 8 to about 16 carbon atoms, an optionally substituted aryl group containing 6 to 20 carbon atoms, or from about 6 to 16 carbon atoms, and a heteroaryl group containing 3 to 26 carbon atoms, or from about 3 to 20 carbon atoms, or from about 3 to about 10 carbon atoms;
M, R³, and R⁴ are each independently selected from the group consisting of O, S, and Se; and
X is selected from the group consisting of C and N.

4. The photodetector of any one of sentences 1-3, wherein the hole transport component may include one or more conducting materials with a work function range between 4.5-5.5 eV.

5. The photodetector of any one of sentences 1-4, wherein the electron acceptor may include fullerenes, non-fullerene acceptors (NFAs), polymers or any material which can serve as an electron acceptor.

6. The photodetector of any one of sentences 1-5, wherein the electron acceptor may be selected from the group consisting of [6,6]-phenyl-C₇₁-butyric acid methyl ester ([70]PCBM), [60]PCBM, PCBM, C₆₀, C₇₀, fullerenes, 3,4,9,10-perylenetetracarboxylic dianhydride (PTCDA), 2,2′-((2Z,2′Z)-((12,13-bis(2-ethylhexyl)-3,9-diundecyl-12,13-dihydro-[1,2,5]thiadiazolo[3,4-e]thieno[2″,3″:4′,5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1-diylidene))dimalononitrile (BTP-4F), and combinations thereof.

7. The photodetector of any one of sentences 1-6, wherein the photodetector may be configured to detect radiation spanning the visible and infrared.

8. The photodetector of any one of sentences 1-7, wherein the one or more insulating materials may be integrated within the organic photoactive layer.

9. The photodetector of any one of sentences 1-8, wherein the one or more insulating materials may include an insulating polymer.

10. The photodetector of any one of sentences 1-8, wherein the one or more insulating materials may be selected from the group consisting of polyethylene, polystyrene, polysulfone, polymethyl(methacrylate), polycarbonate, polyisobutylene, polylactic acid, polyvinylchloride, polyvinylpyrrolidone, polypropylene, polyethylene terephthalate, acrylonitrile butadiene styrene, and any other polymer.

11. The photodetector of any one of sentences 2-10, wherein the one or more insulating materials may be located within the heterojunction or the one or more photoactive layers.

12. The photodetector of any one of sentences 1-11, wherein at least one electrode may include transparent conducting oxides, for example, indium tin oxide (ITO), tin oxide (TO), gallium indium tin oxide (GaITO), and zinc indium tin oxide (ZITO); thin metal layers having a thickness of 50-300 nm; transparent conducting polymers, for example, poly(3,4,-ethylenedioxythiophene), (PEDOT), poly(3,4-ethylenedioxythiophene):polystyrene sulfonate (PEDOT:PSS), polyaniline, and polypyrrole, or any other electrically conductive material.

13. The photodetector of any one of sentences 1-12, wherein said optoelectronic device may be configured to generate an electrical current with reduced noise by at least an order of magnitude under bias up to ±5V in response to incident radiation relative to an optoelectronic device in the absence of the narrow bandgap electron donor.

14. In a third aspect, the present invention relates to a method for producing the photodetector of any one of sentences 1-13 comprising steps of:
mixing the one or more photoactive material electron donors with the electron acceptor and the one or more insulating materials in a solvent to form the bulk heterojunction.
depositing a film of the bulk heterojunction onto a substrate; and
depositing the cathode and anode onto the bulk heterojunction to form the photodetector.

15. The method of sentence 14, wherein the bulk heterojunction may be deposited via a method selected from the group consisting of spin coating, spray coating, blade coating, dip coating, screen printing, flexographic printing, slit coating, and ink-jet printing.

16. The method of any one of sentences 14-15, wherein the first electrode may be deposited onto the blended film via thermal evaporation in a vacuum chamber at a pressure of about 1×10 −6 torr.

17. The method of sentence 16, wherein in the photodetector a combination of the one or more photoactive polymeric electron donors and the electron acceptor may be present in the bulk heterojunction at a concentration of from about 5 mg/ml to about 10 mg/ml.

18. The method of sentence 16, wherein in the photodetector the one or more insulating materials may be present in the bulk heterojunction at a concentration of from about 7 mg/ml to about 30 mg/ml, or a concentration of from about 10 mg/ml to about 25 mg/ml.

19. In a fourth aspect, the present invention relates to a composition comprising an electron donor, an electron acceptor, and an insulating polymer,
wherein the electron donor comprises a polymer according to Formula I or Formula II:

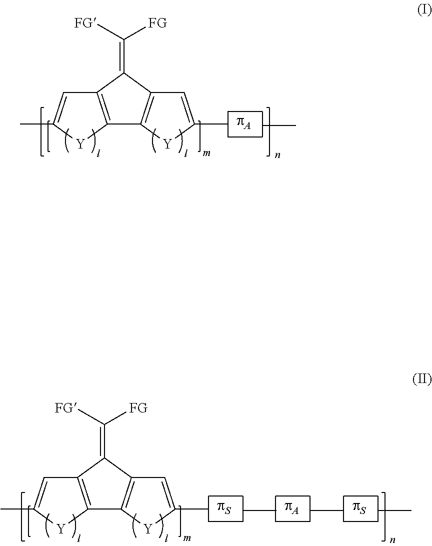

wherein FG and FG′ are each independently selected from the group consisting of hydrogen, an optionally substituted hydrocarbyl group containing 1 to 26 carbon atoms, or from about 5 to 26 carbon atoms, or from about 8 to about 16 carbon atoms, an optionally substituted aryl group containing 6 to 20 carbon atoms, or from about 6 to 16 carbon atoms, an optionally substituted heteroaryl group containing 3 to 26 carbon atoms, or from about 3 to 20 carbon atoms, or from about 3 to about 10 carbon atoms, an optionally substituted aryl group containing 3 to 26 carbon atoms, or from about 3 to 20 carbon atoms, or from about 3 to about 10 carbon atoms,
the optionally substituted aryl group is selected from the group consisting of an arylene group substituted with an alkoxy group containing from 1 to 26 carbon atoms, an alkyl group containing from 1 to 26 carbon atoms, and an alkenyl group containing from 1 to 26 carbon atoms,
m is an integer of at least 1, and n is an integer of greater than 1;
Y is selected from the group consisting of S, BR⁵, PR⁵, Se, Te, NH, and Si,
R⁵ is a C₁-C₂₄ hydrocarbyl group,
π_{S} is a conjugated spacer unit comprising a heteroarylene, wherein the heteroarylene contains 3 to 6 carbon atoms, or about 4 carbon atoms, and wherein the heteroatom of the heteroarylene is selected from the group consisting of S, O, Se, and N, or the heteroatom of the heteroarylene is S, or the heteroarylene has the following structure:

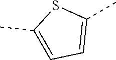

π_{A} is an electron-poor or electron-deficient aromatic moiety that provides a structural unit in the copolymer according to formulae (A)-(F):

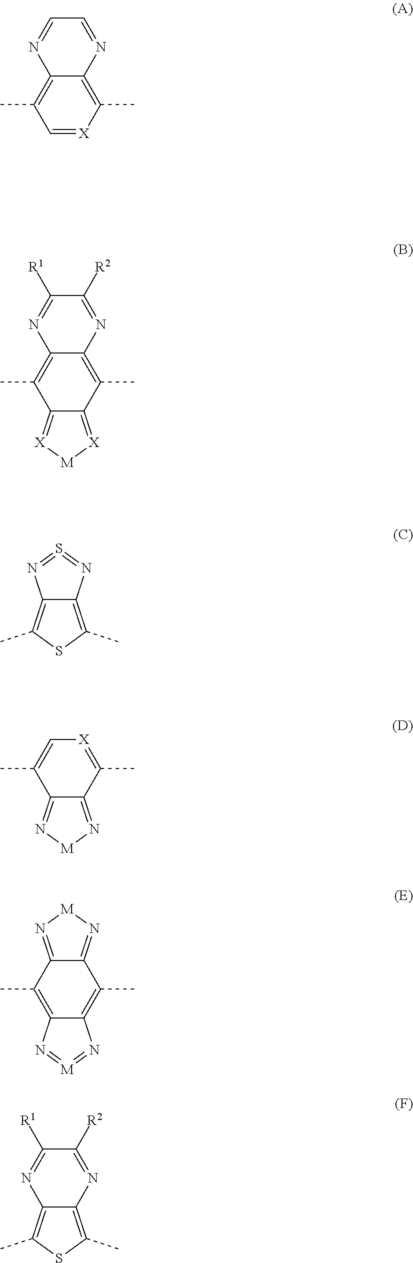

R¹ and R² are each individually selected from a hydrogen, a hydrocarbyl group containing 1 to 26 carbon atoms, or from about 5 to 26 carbon atoms, or from about 8 to about 16 carbon atoms, an alkoxyl group containing 1 to 26 carbon atoms, or from about 5 to 26 carbon atoms, or from about 8 to about 16 carbon atoms, an optionally substituted aryl group containing 6 to 20 carbon atoms, or from about 6 to 16 carbon atoms, and a heteroaryl group containing 3 to 26 carbon atoms, or from about 3 to 20 carbon atoms, or from about 3 to about 10 carbon atoms,
M, R³, and R⁴ are each independently selected from the group consisting of O, S, and Se, and
X is selected from group consisting of C and N.

The invention provides a method and process for preparing an IR sensitive device derived from a multi-component blend of π-conjugated polymers that function as electron donors, an electron acceptor, and an insulating polymer. Such devices demonstrate functionality spanning the visible to infrared spectral regions.

The following definitions of terms are provided in order to clarify the meaning of certain terms as used herein.

As used herein, the term “hydrocarbyl substituent” or “hydrocarbyl group” is used in its ordinary sense, which is well-known to those skilled in the art. Specifically, it refers to a group having a carbon atom directly attached to the remainder of the molecule and having a predominantly hydrocarbon character. Each hydrocarbyl group is independently selected from hydrocarbon substituents, and substituted hydrocarbon substituents containing one or more of halo groups, hydroxyl groups, alkoxy groups, mercapto groups, nitro groups, nitroso groups, amino groups, pyridyl groups, furyl groups, imidazolyl groups, oxygen and nitrogen, and wherein no more than two non-hydrocarbon substituents are present for every ten carbon atoms in the hydrocarbyl group.

As used herein, the term “hydrocarbylene substituent” or “hydrocarbylene group” is used in its ordinary sense, which is well-known to those skilled in the art. Specifically, it refers to a group that is directly attached at two locations of the molecule to the remainder of the molecule by a carbon atom and having predominantly hydrocarbon character. Each hydrocarbylene group is independently selected from divalent hydrocarbon substituents, and substituted divalent hydrocarbon substituents containing halo groups, alkyl groups, aryl groups, alkylaryl groups, arylalkyl groups, hydroxyl groups, alkoxy groups, mercapto groups, nitro groups, nitroso groups, amino groups, pyridyl groups, furyl groups, imidazolyl groups, oxygen and nitrogen, and wherein no more than two non-hydrocarbon substituents is present for every ten carbon atoms in the hydrocarbylene group.

The term “alkyl” as employed herein refers to straight, branched, cyclic, and/or substituted saturated chain moieties of from about 1 to about 100 carbon atoms.

The term “alkenyl” as employed herein refers to straight, branched, cyclic, and/or substituted unsaturated chain moieties of from about 3 to about 10 carbon atoms.

The term “aryl” as employed herein refers to single and multi-ring aromatic compounds that may include alkyl, alkenyl, alkylaryl, amino, hydroxyl, alkoxy, halo substituents, and/or heteroatoms including, but not limited to, nitrogen, oxygen, and sulfur.

As used herein, the term “arylene” is used in its ordinary sense, which is well-known to those skilled in the art. Specifically, it refers to a single and multi-ring aromatic compounds, such as defined in the term “aryl” that is directly attached at two locations of the molecule to the remainder of the molecule by a carbon atom and having a predominantly hydrocarbyl character. Each arylene group is independently selected from divalent single and multi-ring aromatic compounds, and substituted divalent hydrocarbon substituents containing alkyl, alkenyl, alkylaryl, amino, hydroxyl, alkoxy, halo substituents, and/or heteroatoms including, but not limited to, nitrogen, oxygen, and sulfur.

Additional details and advantages of the disclosure are set forth in part in the description which follows. The details and advantages of the disclosure may be realized and attained by means of the elements and combinations particularly pointed out in the appended claims. It is to be understood that both the foregoing general description and the following detailed description are exemplary and explanatory only and are not restrictive of the disclosure and that the claims define the scope of the invention.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The drawings, which are incorporated in and form a portion of the specification, illustrate certain aspects of the invention and, together with the entire specification, are meant to explain preferred embodiments of the present invention to those skilled in the art. The drawings supplement the specification and are intended to illustrate further the invention and its advantages.

FIG. 1 shows a schematic representation of a structure of an organic photodetector.

FIG. 2 shows chemical structures of active materials and insulating materials used in the devices of the invention.

FIG. 3A shows a graphical representation of the external quantum efficiency (EQE) of active blends of materials comprised of the photoactive polymer electron donor, (poly(4-(5-(4-(3,5-bis(dodecyloxy)benzylidene)-4H-cyclopenta[2,1-b:3,4-b′]dithiophen-2-yl)thiophen-2-yl)-6,7-dioctyl-9-(thiophen-2-yl)-[1,2,5]thiadiazolo[3,4-g]quinoxaline), a ‘PCBM’ specifically [6,6]-phenyl-C₇₁-butyric acid methyl ester ([70]PCBM) as the electron acceptor, and an insulating component in the infrared region combined with various plastics at a concentration of 20 mg/mL fabricated into a photodiode under zero bias.

FIG. 3B show a graphical representation of the external quantum efficiency (EQE) of active blends of materials comprised of the photoactive polymer electron donor, (poly(4-(5-(4-(3,5-bis(dodecyloxy)benzylidene)-4H-cyclopenta[2,1-b:3,4-b′]dithiophen-2-yl)thiophen-2-yl)-6,7-dioctyl-9-(thiophen-2-yl)-[1,2,5]thiadiazolo[3,4-g]quinoxaline), a ‘PCBM’ specifically [6,6]-phenyl-C₇₁-butyric acid methyl ester ([70]PCBM) as the electron acceptor, and an insulating component in the infrared region combined with various plastics at a concentration of 20 mg/mL fabricated into a photodiode under an applied bias of −2 V.

FIG. 4A shows a graphical representation of the specific detectivity (D*) of active blends with (poly(4-(5-(4-(3,5-bis(dodecyloxy)benzylidene)-4H-cyclopenta[2,1-b:3,4-b′]dithiophen-2-yl)thiophen-2-yl)-6,7-dioctyl-9-(thiophen-2-yl)-[1,2,5]thiadiazolo[3,4-g]quinoxaline) and [70]PCBM in the infrared region with various insulating polymers at a concentration of 20 mg/mL fabricated in a photodiode under zero bias.

FIG. 4B show a graphical representation of the specific detectivity (D*) of active blends with (poly(4-(5-(4-(3,5-bis(dodecyloxy)benzylidene)-4H-cyclopenta[2,1-b:3,4-b′]dithiophen-2-yl)thiophen-2-yl)-6,7-dioctyl-9-(thiophen-2-yl)-[1,2,5]thiadiazolo[3,4-g]quinoxaline) and [70]PCBM in the infrared region with various insulating polymers at a concentration of 20 mg/mL fabricated in a photodiode under an applied bias of −2 V.

FIG. 5A shows a graphical representation of the noise spectra with applied bias with the plastic additive of the present invention.

FIG. 5B shows a graphical representation of the noise spectra with applied bias without the plastic additive of the present invention.

FIG. 6A shows an atomic force microscopy image of the height of an active blend comprised of the photoactive polymer electron donor, an electron acceptor, and an insulating component.

FIG. 6B shows an atomic force microscopy image of the phase of an active blend comprised of the photoactive polymer electron donor, an electron acceptor, and an insulating component.

FIG. 7A shows the chemical structures of the donor (poly(4-(5-(4-(3,5-bis(dodecyloxy)benzylidene)-4H-cyclopenta[2,1-b:3,4-b′]dithiophen-2-yl)thiophen-2-yl)-6,7-dioctyl-9-(thiophen-2-yl)-[1,2,5]thiadiazolo[3,4-g]quinoxaline)) (CDT-TQ) and fullerene acceptor [6,6]-phenyl C₇₁-buytic acid methyl ester (PC₇₁BM).

FIG. 7B shows the device layer structure of the organic photodetector (OPD) with glass/ITO/PEDOT:PSS/ZnO/Al.

FIG. 7C shows an energy-level diagram of the device of the present invention.

FIG. 7D shows the measured responsivity and external quantum efficiency (EQE) of a control device at 0 V and −2.0 V bias.

FIG. 7E shows the noise spectral density of the control device from 0 V to −2V.

FIG. 7F shows the specific detectivity (D*) of the control device.

FIG. 8A shows voltage-dependent dark current density (J-V) curves of the OPDs in the dark with polystyrene (PS), polymethyl methacrylate (PMMA), and polysulfone (PSU) at concentrations of 5 and 20 mg/mL. The control is indicated by the dashed lines.

FIG. 8B shows the external quantum efficiency (EQE) and R under −2 V bias.

FIG. 8C shows the specific detectivity of the devices at −2 V bias with the concentrations of 5 and 20 mg/mL.

FIG. 9A shows the specific detectivity of the polysulfone (PSU) device at 20 mg/mL concentration under an applied bias.

FIG. 9B shows the noise spectral density of the PSU device at various concentrations at −2 V.

FIG. 9C shows a chart of bias-dependent EQE and specific detectivity.

FIG. 10 shows the height profile using atomic force microscopy (AFM) (images a-d of FIG. 10) and phase images (images e-h of FIG. 10) of CDT-TQ:PC₇₁BM:PSU blends with PSU concentrations of 0, 5, 10, and 20 mg/mL, respectively. Images I-K of FIG. 10 show atomic force microscope-infrared spectroscopy (AFM-IR) topography of the PSU ternary blend at concentrations of 5, 10, and 20 mg/mL. Color coded as PC₇₁BM (green), CDT-TQ (pink), and PSU (blue).

FIG. 11 shows a capacitance-frequency plot in image a) and the density of states of OPDs with PSU at various concentrations in image b).

FIG. 12 shows J-V curves of devices with other insulators at varying concentrations including polystyrene (PS), polysulfone (PSU), and polymethylmethacrylate (PMMA).

FIG. 13 shows in image a) current density normalized to the electric field at each concentration's thickness at 180 nm, 340 nm, 570 nm, 580 nm for the concentrations of 0, 5, 10, and 20 mg mL⁻¹, respectively. Image b) of FIG. 13 shows J-V curves of the devices comparing the thickness of BHJ films with and without PSU (20 mg mL⁻¹) at the same thickness, 180 nm.

FIG. 14 shows overlayed AFM-IR images of the ternary blends at various concentrations of PSU insulator.

FIG. 15 shows AFM-IR images of each component: CDT-TQ (1588 cm⁻¹), PSU (1490 cm⁻¹), and PC₇₁BM (1737 cm⁻¹).

FIG. 16 shows the density of states extracted from the capacitance frequency plots from FIG. 11. The black lines are best fit lines from equation 5.

FIG. 17 shows in image a) capacitance-frequency characteristics of PSU devices at varying concentrations at −2 V bias and in image b) the density of states extracted from panel (a)

FIG. 18 shows a space charge-limited current (SCLC) mobility curve of the control device and the device with a concentration of 20 mg/mL PSU.

### DETAILED DESCRIPTION OF THE INVENTION

The present invention demonstrates that incorporating wide-bandgap insulating polymers within the BHJ suppresses noise current by dilution of the transport and trapping sites as determined using capacitance-frequency analysis. The resulting D* of NIR-SWIR OPDs operating from 600-1400 nm under an applied bias of −2 V was improved by two orders of magnitude from 10⁸ Jones to 10¹⁰ Jones when the polymer PSU was incorporated within the blends. This strategy may be utilized to reduce noise in IR-OPDs using insulating polymers and allow the practical use of IR-OPDs under a reverse bias operation.

In one aspect, the present invention relates to a photodetector configured for converting light to an electronic signal, including:
a substrate comprising a hole transport component and electron transport component;
one or more photoactive layers comprising:
   one or more semiconducting materials that comprise a photoactive small molecule, oligomeric, or polymeric electron donor and an electron acceptor, wherein the electron donor has a narrow bandgap of less than 1.4 eV; and
   one or more insulating materials, wherein the one or more semiconducting materials and the one or more insulating materials are present in a weight ratio of 1:0.1 to about 1:100,
a cathode in electrical contact with the electron or hole transport component; and;
an anode in electrical contact with the hole or electron transport component.

In a second aspect, the present invention relates to photodetector configured for converting light to an electronic signal, comprising:
a substrate comprising a hole transport component or an electron transport component, one or more photoactive layers comprising:
   a heterojunction of two or more semiconducting materials that comprise a photoactive small molecule, oligomeric, or polymeric electron acceptor and an electron donor present in a weight ratio of from about 1:0.1 to about 1:100, wherein the electron donor has a narrow bandgap of less than 1.4 eV, and
   one or more insulating materials, wherein the two or more semiconducting materials and the one or more insulating materials are present in a weight ratio of 1:0.1 to about 1:100,
a cathode in electrical contact with the bulk heterojunction; and
an anode in electrical contact with the bulk heterojunction.

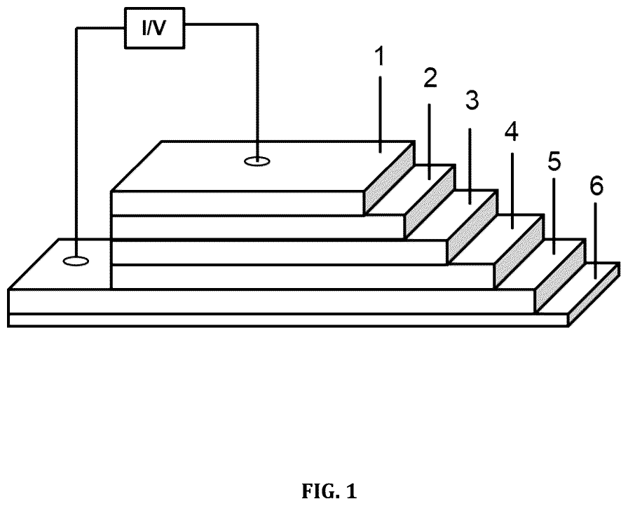

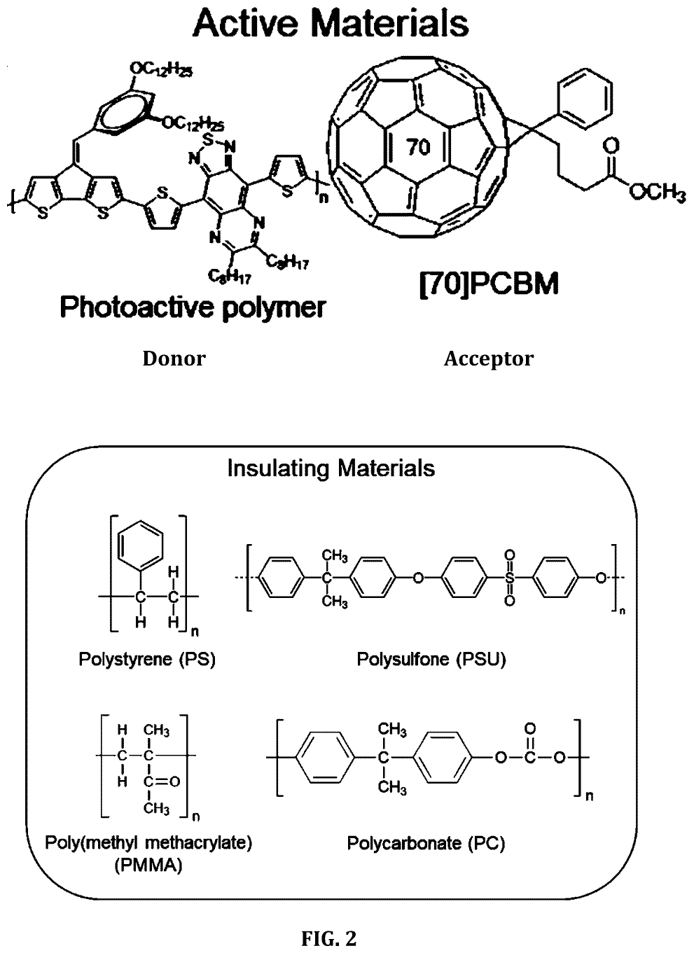

FIG. 1 shows an example of the structure of a bulk heterojunction organic photodiode/photodetector. The diode consists of multiple organic layers, which are applied to a substrate 6 containing two electrodes 5, 1. In this example, the organic photodiode has two organic layers, an electron transport layer 2 and a hole transport layer 4.

One or more additional layers may be provided between the anode and the cathode. A hole-transporting layer and/or a hole-injecting layer may be provided between the anode and the bulk heterojunction layer. An electron-transporting layer and/or an electron injecting layer may be provided between the cathode and the bulk heterojunction layer.

Substrate 6, which supports the film is typically glass and can be other solid materials (rigid, semi-flexible, or flexible) including quartz, metal, plastic, silicon, silica, mineral, ceramic, semiconducting material, or any combination of these. The lower electrode is utilized as the anode 5 and the upper electrode 1 is utilized as the cathode. This electrode configuration and its polarity can also be presented in an inverted fashion. Suitable semiconducting materials are those that comprise a photoactive small molecule, oligomeric, or polymeric electron donor and an electron acceptor, preferably present in a weight ratio of from about 0.5 to about 1:3 or from 1:1 to 1:2.

The anode 5, for example, may be formed from indium-tin oxide (ITO), tin oxide (TO), gallium indium tin oxide (GaITO), zinc indium tin oxide (ZITO), indium zinc oxide (IZO), gold, palladium, silver, or platinum and is typically manufactured by sputtering, vapor deposition, and printing processes.

The hole transport layer 4, for example, may be comprised of transparent conductive polymers such as fused or unfused polythiophenes, optionally poly(ethylenedioxythiophene) (PEDOT) having a charge-balancing polyanion, optionally polystyrene sulfonate (PSS). Additional examples may include polyaniline and polypyrrole.

The photoactive layer 3, for example, may be comprised of an electron donor, an electron acceptor, and an insulating component. This insulating component may include but is not limited to polyethylene, polystyrene (PS), polysulfone (PSU), polymethyl(methacrylate) (PMMA), polycarbonate, polyisobutylene, polylactic acid, polyvinylchloride, polyvinylpyrrolidone, polypropylene, polyethylene terephthalate, acrylonitrile butadiene styrene, or any other suitable polymer.

The electron donors of the present disclosure may have a narrow bandgap of less than 1.4 eV, or from about 0 to about 1.4, or from about less than 1.4 to greater than 0.01 to less than 1 eV. For example, the electron donors of the present disclosure may comprise a polymer according to Formula I or Formula II:

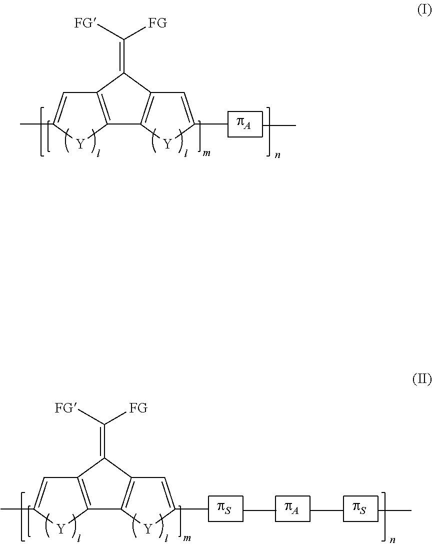

wherein FG and FG′ are each independently selected from the group consisting of hydrogen, an optionally substituted hydrocarbyl group containing 1 to 26 carbon atoms, or from about 5 to 26 carbon atoms, or from about 8 to about 16 carbon atoms, an optionally substituted aryl group containing 6 to 20 carbon atoms, or from about 6 to 16 carbon atoms, an optionally substituted heteroaryl group containing 3 to 26 carbon atoms, or from about 3 to 20 carbon atoms, or from about 3 to about 10 carbon atoms, and an optionally substituted aryl group containing 3 to 26 carbon atoms, or from about 3 to 20 carbon atoms, or from about 3 to about 10 carbon atoms,
the optionally substituted aryl group is selected from the group consisting of an arylene group substituted with an alkoxy group containing from 1 to 26 carbon atoms, an alkyl group containing from 1 to 26 carbon atoms, and an alkenyl group containing from 1 to 26 carbon atoms,
m is an integer of at least 1, and n is an integer of greater than 1,
Y is selected from the group consisting of S, BR⁵, PR⁵, Se, Te, NH, and Si,
R⁵ is a C₁-C₂₄ hydrocarbyl group,
π_{S} is a conjugated spacer unit comprising a heteroarylene, wherein the heteroarylene contains 3 to 6 carbon atoms, or about 4 carbon atoms, and wherein the heteroatom of the heteroarylene is selected from the group consisting of S, O, Se, and N, or the heteroatom of the heteroarylene is S, or a heteroarylene according to the following structure:

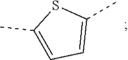

π_{A} is an electron-poor or electron-deficient aromatic moiety that provides a structural unit in the copolymer according to formulae (A)-(F):

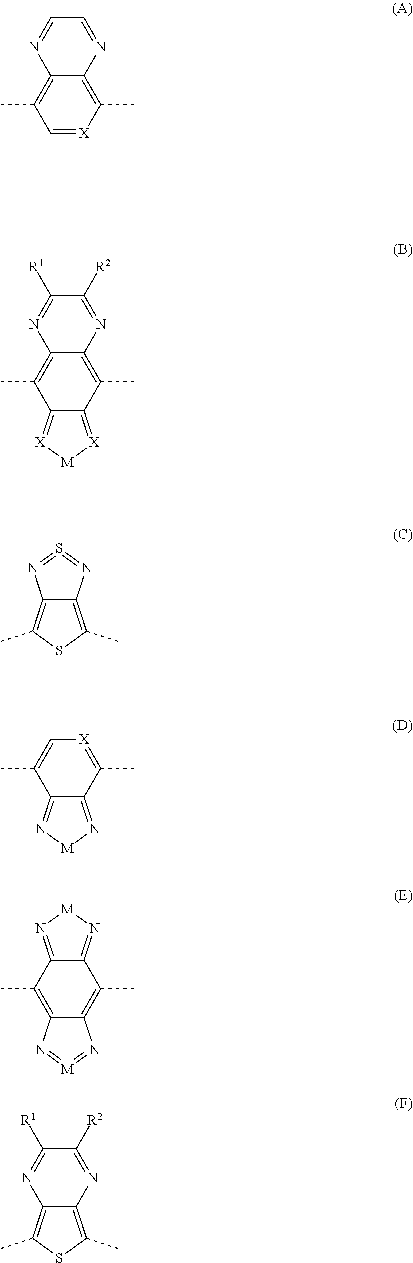

wherein R¹ and R² are each individually selected from a hydrogen, a hydrocarbyl group containing 1 to 26 carbon atoms, or from about 5 to 26 carbon atoms, or from about 8 to about 16 carbon atoms, an alkoxyl group containing 1 to 26 carbon atoms, or from about 5 to 26 carbon atoms, or from about 8 to about 16 carbon atoms, an optionally substituted aryl group containing 6 to 20 carbon atoms, or from about 6 to 16 carbon atoms, and a heteroaryl group containing 3 to 26 carbon atoms, or from about 3 to 20 carbon atoms, or from about 3 to about 10 carbon atoms,
M, R³, and R⁴ are each independently selected from the group consisting of O, S, and Se, and
X is selected from the group consisting of C and N.

Other suitable examples of electron donor polymers are disclosed in CN108365098, WO 2017/191466, US20190229269, and US2022/0102658, which electron donor polymers are hereby incorporated by reference herein. For example, the electron donor polymers may also include (poly(4-(5-(4-(3,5-bis(dodecyloxy)benzylidene)-4H-cyclopenta[2,1-b:3,4-b′]dithiophen-2-yl)thiophen-2-yl)-6,7-dioctyl-9-(thiophen-2-yl)-[1,2,5]thiadiazolo[3,4-g]quinoxaline), and a poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (PBDB-T), having the following structure:

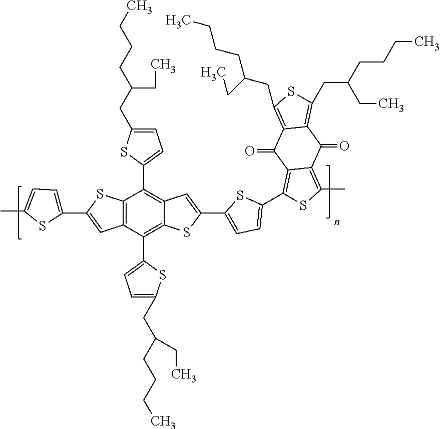

wherein n is an integer greater than 1.

The electron donors of the present invention may have in-chain donors and strong heterocyclic acceptor components. The π_{S} and π_{A} components of Formulae (I)-(II) hybridize with one another to collectively lower the highest occupied molecular orbital—lowest unoccupied molecular orbital (HOMO-LUMO) levels to provide bandgaps below 1.4 eV, or lower than 1.0 eV. This reduction in bandgap leads to reduced thermal noise generation.

The electron acceptors of the present invention may comprise fullerene and non-fullerene acceptors, for example molecules and polymers, having extended, rigid, π-conjugated electron-deficient frameworks that can facilitate exciton and charge delocalization. Suitable examples of non-fullerene acceptors may include substituted or unsubstituted 3,9-bis(2-methylene-(3-(1,1-5 dicyanomethylene)-indanone))-5,5,11,11-tetrakis(4-hexylphenyl)-dithieno[2,3-d:2′,3′-d′]-s-indaceno[1,2-b:5,6-b′]dithiophene (ITIC):

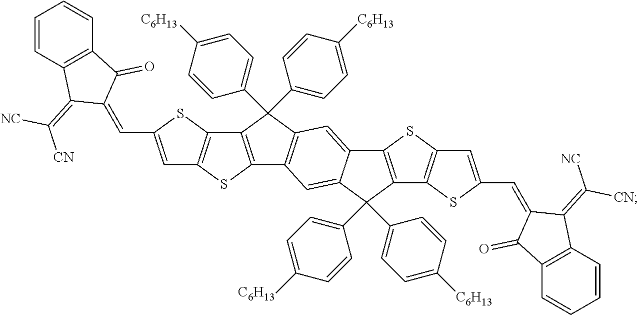

or a compound according to:

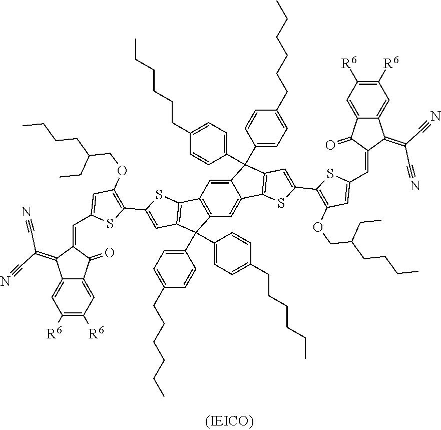

wherein R⁶ may be a halogen, for example Br, Cl, and F; a polyaromatic hydrocarbon, perylene diimide (PDI), or derivatives thereof, for example, ITIC-2F, alkylated ITIC, ITIC-Th, and IEICO-4F, 3,4,9,10-perylenetetracarboxylic dianhydride (PTCDA), 2,2′-((2Z,2′Z)-((12,13-bis(2-ethylhexyl)-3,9-diundecyl-12,13-dihydro-[1,2,5]thiadiazolo[3,4-e]thieno[2″,3″:4′,5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1-diylidene))dimalononitrile (BTP-4F), and combinations thereof.

Suitable examples of fullerene may include C₆₀, C₇₀, C₇₈, and C₈₄ fullerenes or a derivative thereof including, without limitation, PCBM-type fullerene derivatives (including phenyl-c61-butyric acid methyl ester (C₆₀PCBM) and phenyl-C71-butyric acid methyl ester (C₇₀PCBM), TCBM-type fullerene derivatives (e.g. tolyl-C61-butyric acid methyl ester (C₆TCBM)), and ThCBM-type fullerene derivatives (e.g. thienyl-C61-butyric acid methyl ester (C₆₀ThCBM)).

The photoactive organic layers may be applied over an area, for example, by spin coating, spray coating, blade coating, dip coating, screen printing, flexographic printing, slit coating, ink-jet printing, etc. These processes permit a large area to be coated, since no structuring of the semiconductor is required inside the active sensor area.

The cathode 1 may, for example, be formed from Ca, Al, Ag, Pd, Pt, Au, Au alloy, LiF, Mg, indium-tin oxide (ITO), tin oxide (TO), gallium indium tin oxide (GaITO), or zinc indium tin oxide (ZITO) and is typically applied by thermal evaporation or electron beam evaporation but can also be applied using various methods including printing. The work functions of the two electrodes forms an internal electrical field which separates the electron hole pairs caused by the absorption of light.

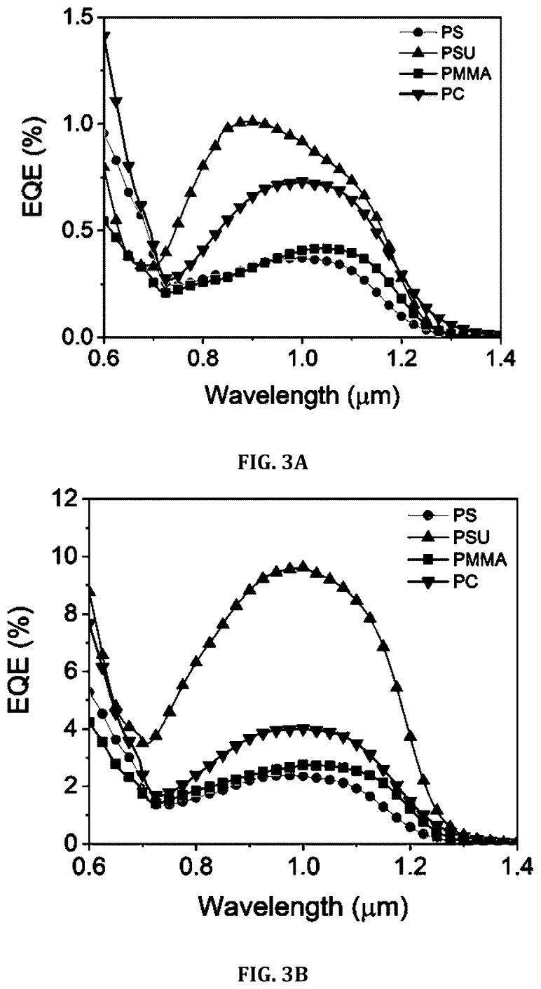

FIGS. 3A and 3B show the external quantum efficiency as a result of the reverse voltage applied (photoconductive effect). Increasing the voltage allows an improvement up to a certain range.

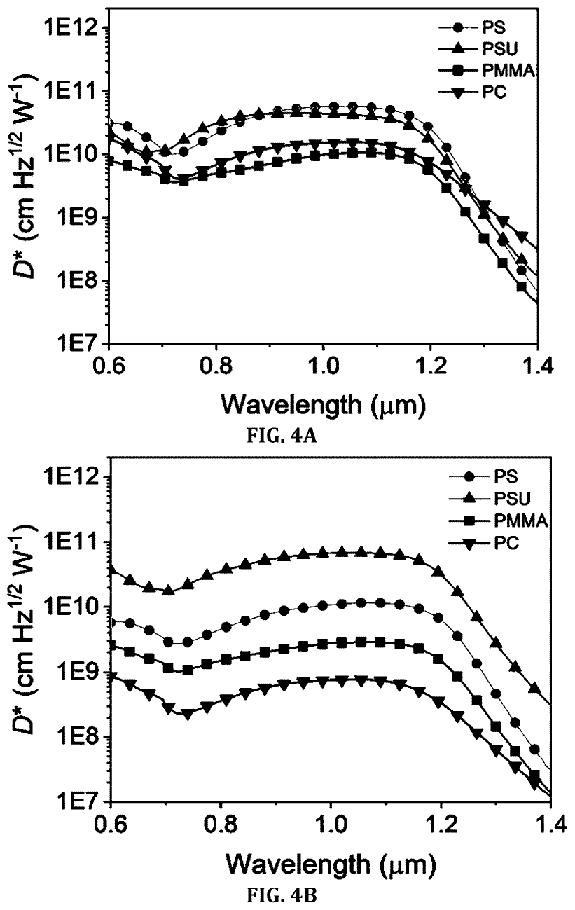

FIGS. 4A and 4B show the specific detectivities as a result of the reverse voltage applied for each plastic blend. As can be seen, the blend with polysulfone under reverse bias does not show increased noise signals.

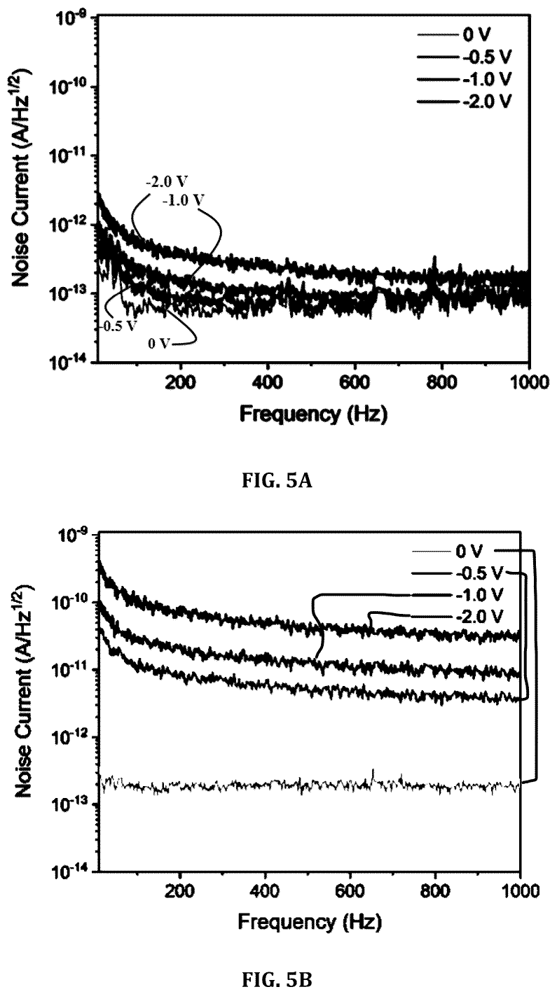

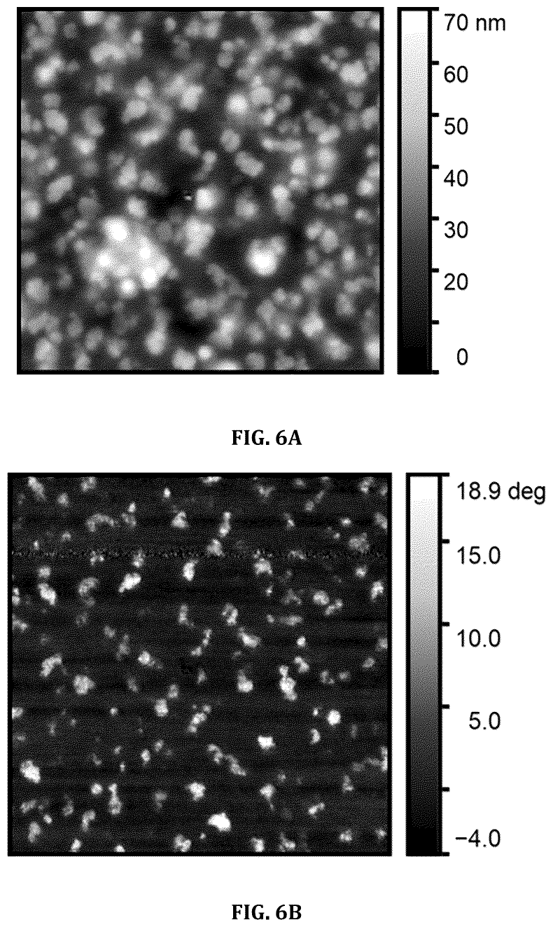

FIGS. 5A and 5B show the noise spectrum as a result of the reverse voltage applied for blends with and without polysulfone.

In use, the photodetectors as described in this disclosure may be connected to a voltage source for applying a reverse bias to the device and/or a device configured to measure photocurrent. The voltage applied to the photo detectors may be variable. In some embodiments, the photodetector may be continuously biased when in use.

The proposed methods and devices enable photoresponsive devices to be produced cost-effectively using solution-processing methods. These devices range from smaller single point devices to large area devices which span different technologies, and may be applied in the imaging, sensing, lighting, automotive, environmental, and space industries. By contrast with previously known photodetectors that are operated in the visible and infrared regions, the new photodetectors, which contain blends of conventional plastics, are not complex or expensive to produce and may be mounted on flexible substrates by simple printing processes. Furthermore, this method provides a simple approach to mitigate noise signals in organic photoresponsive devices under a reverse bias operation. This method also provides a means to modify the active layer, for example creating thick layers on CMOS components, and improving stability. This method can also provide an improved thermal stability relative to other methods.

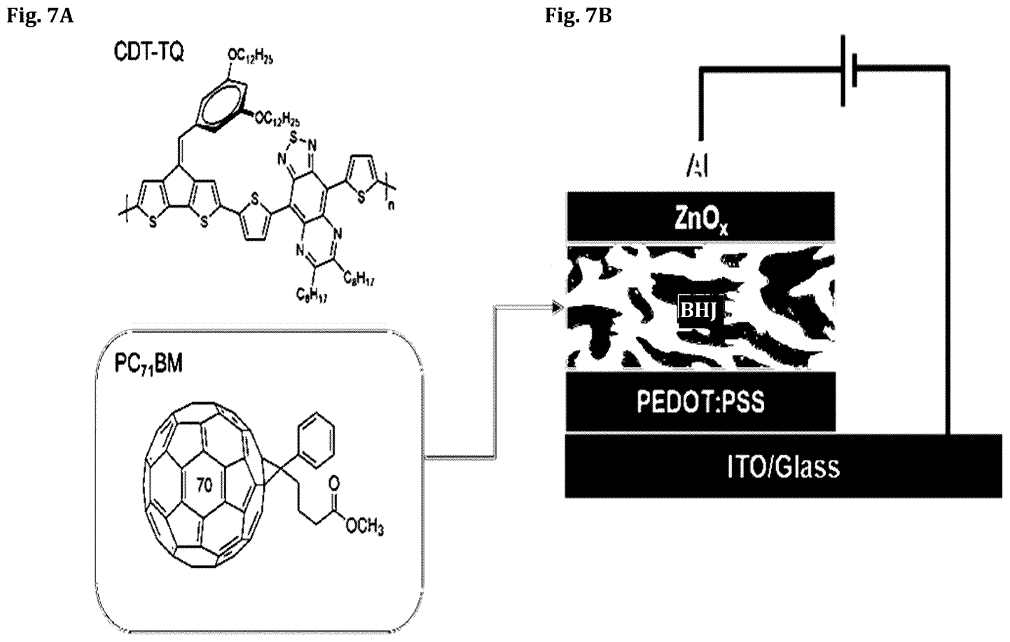

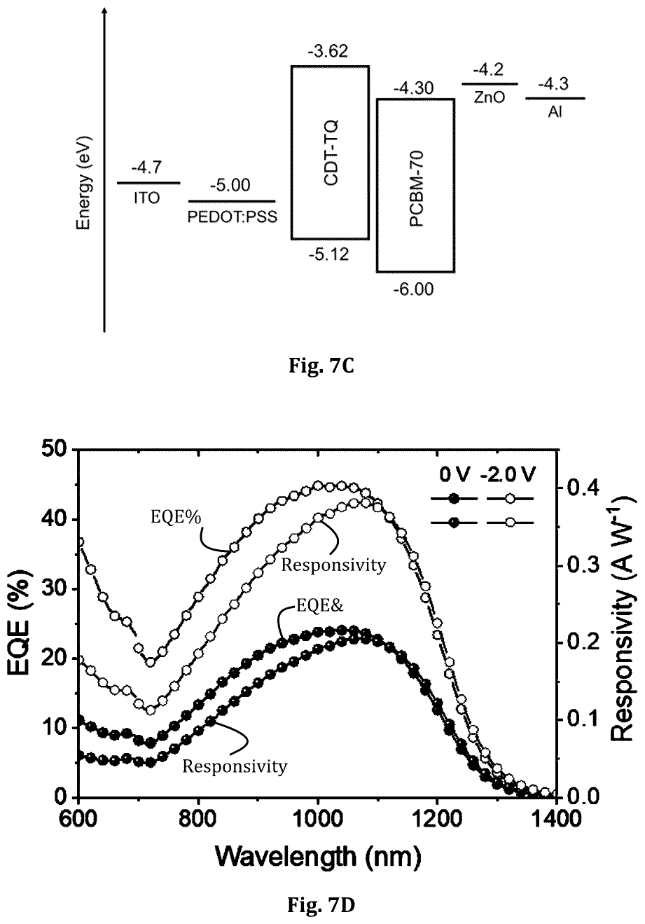

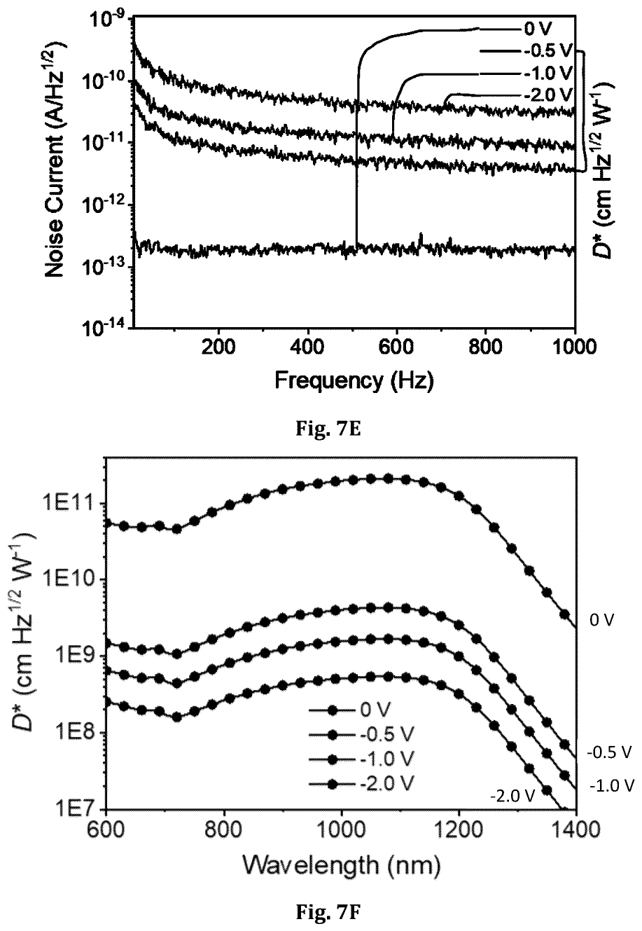

Examples were carried out to demonstrate a versatile strategy to reduce the device noise, which relies on the incorporation of wide bandgap insulators within the BHJ. The incorporation of insulators has been previously demonstrated in organic photovoltaics (OPVs) and organic field-effect transistors (OFETs). It was reported to have retained the optical and electronic properties of the active material while improving their performance.²⁴⁻²⁹ However, there have been few reports in incorporating insulators for the optimization of OPDs.^{30, 31} Therefore, the present invention utilized a model system comprised of an IR sensitive donor-acceptor conjugated polymer (poly(4-(5-(4-(3,5-bis(dodecyloxy)benzylidene)-4H-cyclopenta[2,1-b:3,4-b′]dithiophen-2-yl)thiophen-2-yl)-6,7-dioctyl-9-(thiophen-2-yl)-[1,2,5]thiadiazolo[3,4-g]quinoxaline)) (CDT-TQ) and fullerene acceptor [6,6]-phenyl C₇₁-buytic acid methyl ester (PC₇₁BM) as the photoactive layer (FIG. 7A). The device structure consists of indium tin oxide [ITO]/poly(3,4-ethylenedioxythiophene):poly(styrenesulfonate) [PEDOT:PSS]/CDT-TQ:PC₇₁BM/ZnO/Al (FIG. 7B). At 0 V, BHJ OPDs utilizing this combination achieved an external quantum efficiency (EQE) of 25% at 1100 nm with measurable response to 1400 nm. This gives a responsivity (R) of 0.20 A W⁻¹ at 1100 nm, among the highest value reported for polymer-based OPDs (FIG. 7C) (FIG. 7D). This value for R achieves a level of performance in the NIR that is statistically comparable to that of state-of-the-art SiPDs (Hamamatsu S1133), Ge, and InGaAs.

The specific detectivity (D*) is the main figure of merit that allows a comparison of performance between different detector technologies, and is the signal-to-noise ratio given by:

$${D}^{*} = \frac{q λ \sqrt{A}}{hc} \frac{EQE}{{S}_{n}} = \frac{R \sqrt{A}}{{S}_{n}} \qquad ( 1 )$$

where q is the elementary charge, λ the wavelength, h the Planck constant, c the speed of light, A the device area in cm², R the responsivity in A W⁻¹, and Sₙ is the noise current spectral density (total noise of a photodiode) in A Hz^{-1/2}. Applying a reverse bias of −2 V resulted in a concomitant increase in the EQE to 40% and an increase in R from 0.20 A W⁻¹ to 0.37 A W⁻¹ (FIG. 7D). However, this was accompanied by a reduction in D* from 2.1×10¹¹ Jones at 0 V to 5.3×10⁸ Jones at −2 V (FIG. 7F). The magnitude of this reduction is comparable to many other contemporary materials systems. The total noise current was directly measured with a power spectrum analyzer to capture all the contributions to the noise and is given by:

Sₙ(S_{1/f}²+Sₛₕₒₜ²+Sₜₕₑᵣₘₐₗ²)^{1/2} (2)

where Sₛₕₒₜ is the shot noise, Sₜₕₑᵣₘₐₗ is the thermal noise, and S_{1/f} is the flicker noise. The application of a reverse bias resulted in an increase in the total noise Sₙ at 400 Hz from 1.9×10⁻¹³ A Hz^{-1/2} at 0 V up to 1.4×10⁻¹⁰ A Hz^{-1/2} at −2 V (FIG. 7E) thereby reducing the overall D*.

These results demonstrated that achieving a high signal-to-noise ratio in the NIR-SWIR is often challenging due to the inherently large dark currents in narrow bandgap materials systems. In semicrystalline conjugated polymer:fullerene (i.e., D-A) BHJs, sub-bandgap trap states affect charge transport and carrier recombination, thereby increasing Sₙ.^{21, 32, 33} Unlike reverse bias conditions, common to OPD operation, the low level of dark current in the absence of a bias can be substantially affected by the existence/presence of carrier trapping within these sub-bandgap states. However, previous studies have demonstrated that carrier trapping can be suppressed by dilution of the transport and trapping sites of OSCs by blending with a wide-bandgap material or insulator (high bandgap polymer).^{34, 35}

To address and understand these issues, ternary systems comprised of CPDT-TQ:PC₇₁BM combination blended with insulating (high/wide bandgap) polymers including polystyrene (PS), poly(methyl methacrylate) (PMMA), and polysulfone (PSU) were tested. For consistency, devices were fabricated using the same architecture and maintaining a CDT-TQ:PC₇₁BM constant ratio of 1:2, in an analogous manner to the control in FIG. 7 above.

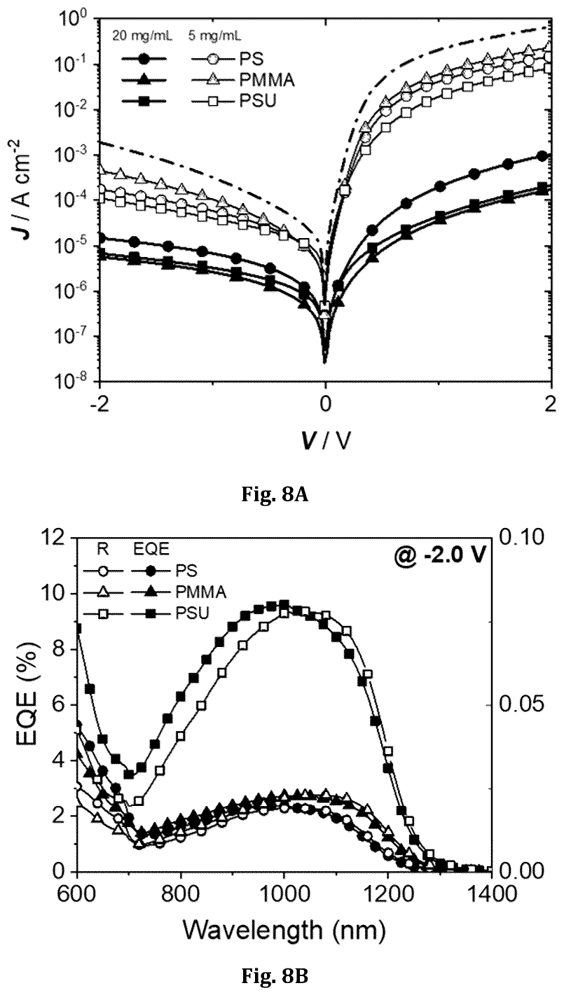

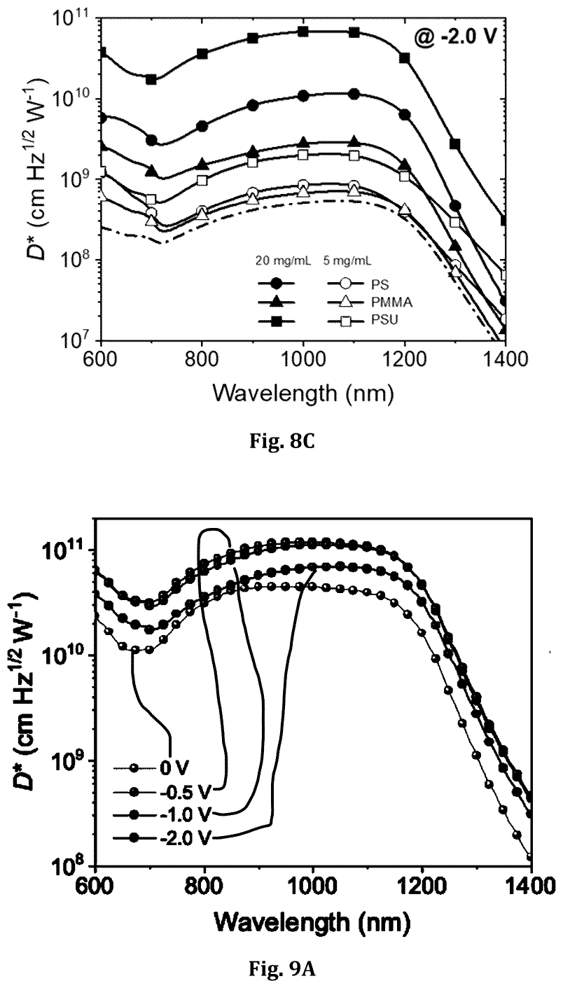

The active layer incorporated different weight ratios (17%, 29%, 45%) of each insulating polymer, which were prepared by first diluting the insulating polymer at a concentration of 5 mg/mL, 10 mg/mL, 20 mg/mL in chlorobenzene, then dissolving CPDT-TQ and PC₇₁BM using this solution in lieu of neat solvent (i.e., control). FIG. 8A shows the dark current density-voltage (J-V) characteristics of the control OPD and those fabricated using different insulating polymers prepared using the 5 and 20 mg/mL solutions. The dark J-V curves demonstrated that as the concentration of insulating polymer increases J_{dark} decreases by approximately three orders of magnitude when compared to the control (1.9×10⁻³ at −2 V bias). Using concentrations of 20 mg/mL, J_{dark} at −2 V was 1.5×10⁻⁵, 5.7×10⁻⁶, and 6.8×10⁻⁶ A cm⁻² for PS, PMMA, and PSU, respectively. This was also accompanied by a decrease in EQE and R as shown in FIG. 8B.

Increasing the insulator concentration decreased the peak EQE from 45% to ˜10% at 1100 nm under −2 V bias for PSU and as low as 2% for PS and PMMA, demonstrating that diluting the active components with an insulating polymer reduces the volumetric light harvesting efficiency of the blends.^{28, 35, 36} Table 1 summarizes the performance parameters of OPDs obtained from PS, PMMA, and PSU using various concentrations of insulating polymer. Examination of D* at −2 V for the control device at −2 V (D*=5.3×10⁸ Jones) and devices using 20 mg mL⁻¹ solutions demonstrated an improvement when employing PS and PMMA (D*=4.7×10⁹ and 2.8×10⁹ Jones, respectively), while the PSU device shows the highest specific detectivity of D*=6.6×10¹⁰ Jones.

TABLE 1
Photodetector performance of CDT-TQ:PC₇₁BM photodiodes with PS, PMMA, and PSU
incorporated at 5, 10, and 20 mg mL⁻¹ at −2 V bias. (Example 5)

| Materials | Sₙ (A Hz^{-1/2})_{@ 400 Hz, -2 V} | J_{-2 V} (A cm⁻²) | R (A W⁻¹)_{@ -2 V, 1100 nm} | D* (cm Hz^{1/2} W⁻¹)_{@ -2 V, 1100 nm} |
|---|---|---|---|---|
| Control | 1.41 × 10⁻¹⁰ | 1.9 × 10⁻³ | 0.37 | 5.3 × 10⁸ |
| PS₅ | 1.82 × 10⁻¹¹ | 2.9 × 10⁻⁵ | 0.07 | 8.3 × 10⁹ |
| PS₁₀ | 8.13 × 10⁻¹³ | 2.7 × 10⁻⁵ | 0.03 | 7.1 × 10⁹ |
| PS₂₀ | 6.88 × 10⁻¹³ | 2.4 × 10⁻⁶ | 0.02 | 4.7 × 10⁹ |
| PMMA₅ | 2.66 × 10⁻¹¹ | 4.5 × 10⁻⁴ | 0.09 | 7.0 × 10⁸ |
| PMMA₁₀ | 6.53 × 10⁻¹² | 1.1 × 10⁻⁴ | 0.04 | 1.2 × 10⁹ |
| PMMA₂₀ | 1.60 × 10⁻¹² | 5.7 × 10⁻⁶ | 0.02 | 2.8 × 10⁹ |
| PSU₅ | 2.17 × 10⁻¹¹ | 1.1 × 10⁻⁴ | 0.21 | 1.9 × 10⁹ |
| PSU₁₀ | 9.12 × 10⁻¹³ | 7.8 × 10⁻⁵ | 0.11 | 2.4 × 10¹⁰ |
| PSU₂₀ | 2.28 × 10⁻¹³ | 6.8 × 10⁻⁶ | 0.07 | 6.6 × 10¹⁰ |

Sₙ—Total Noise Curent - Equation 1
J_{-2 V}—Reverse Dark Current at −2 V bias
R—Responsivity in A W⁻¹
D*—Specific Detectivity - Equation 2

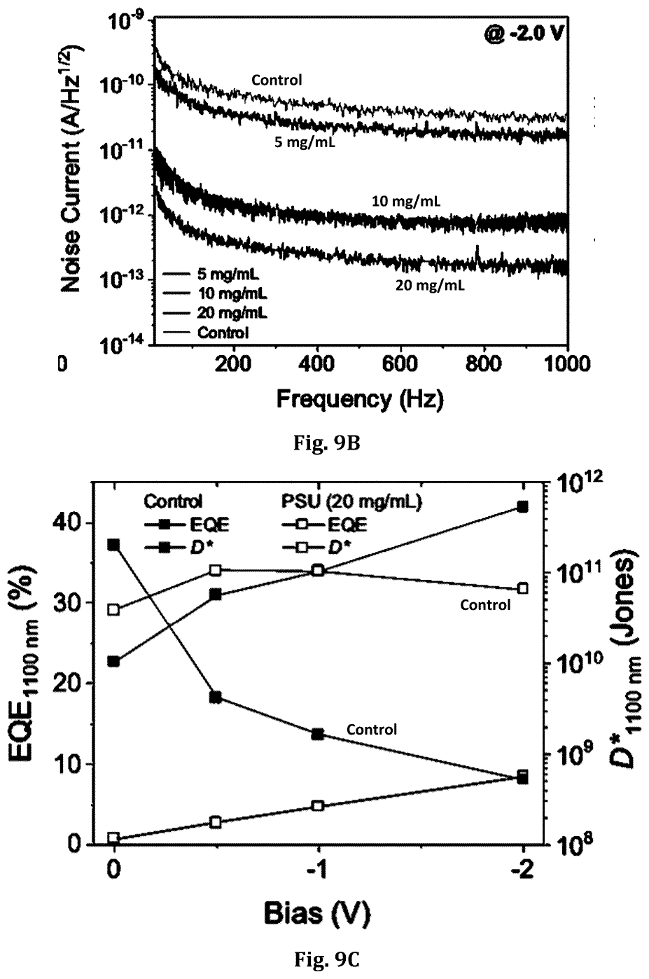

The highest D* at −2 V bias was obtained using PSU, prompting a detailed investigation of this ternary blend. A decrease in J from 1.1×10⁻⁴ to 6.8×10⁻⁶ A cm⁻² was observed as the PSU concentration was increased from 5 mg/mL to 20 mg/mL (17-45 wt %) (FIG. 9A). When it was compared to the control device with no insulator added (Sₙ=1.9×10⁻³ A cm⁻²), this demonstrated a decrease of three orders of magnitude. While the effect of diluting the BHJ with insulator resulted in a decrease in EQE, the total noise current under reverse bias decreased from 1.4×10⁻¹⁰ A Hz^{-1/2} for the control device to 2.3×10⁻¹³ A Hz^{-1/2} at −2.0 V (FIG. 9B). This result is consistent with a major suppression of the dominant contribution to the noise in devices incorporating PSU, resulting in preserving D* upon the application of a bias.

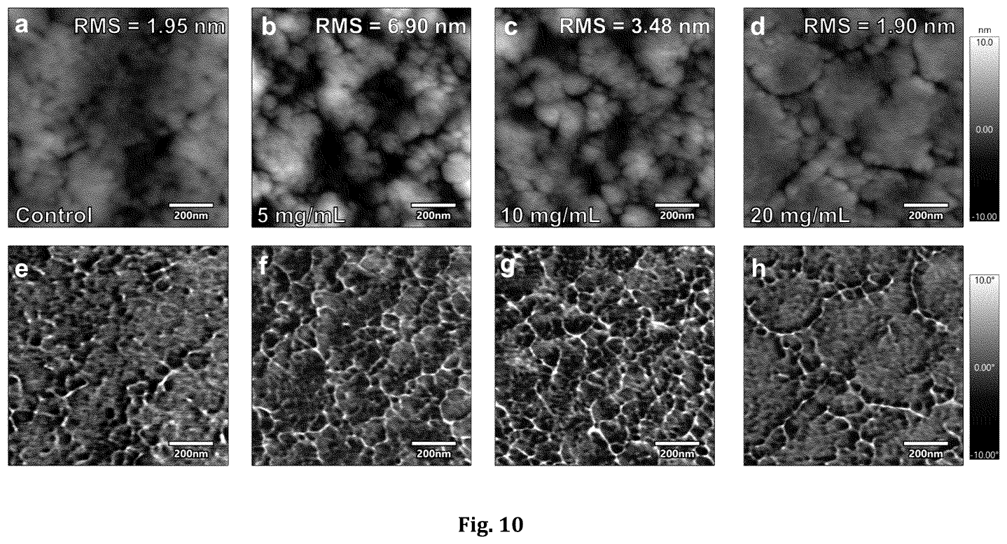

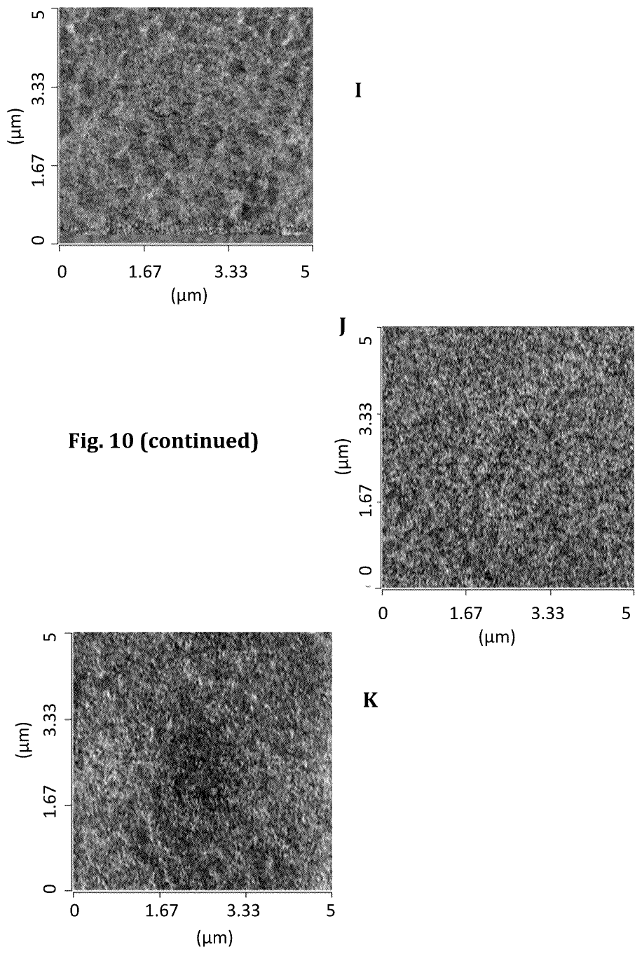

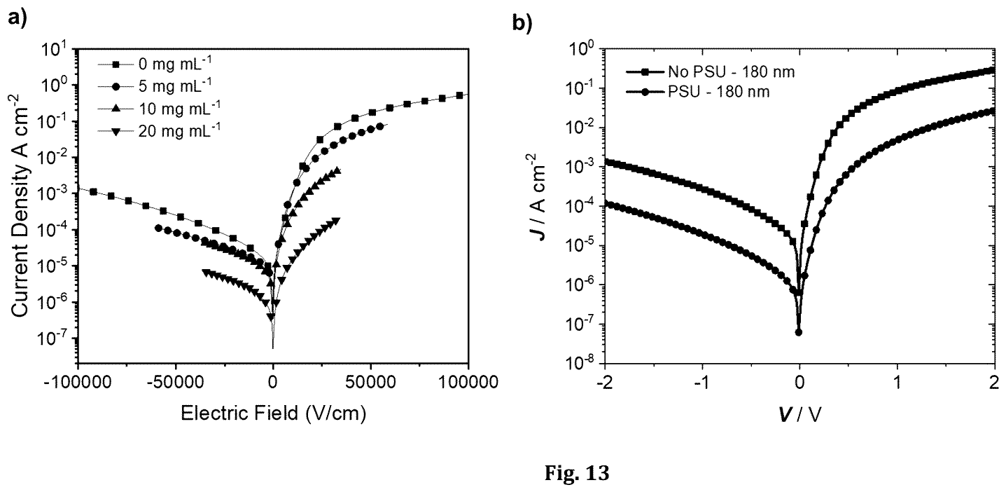

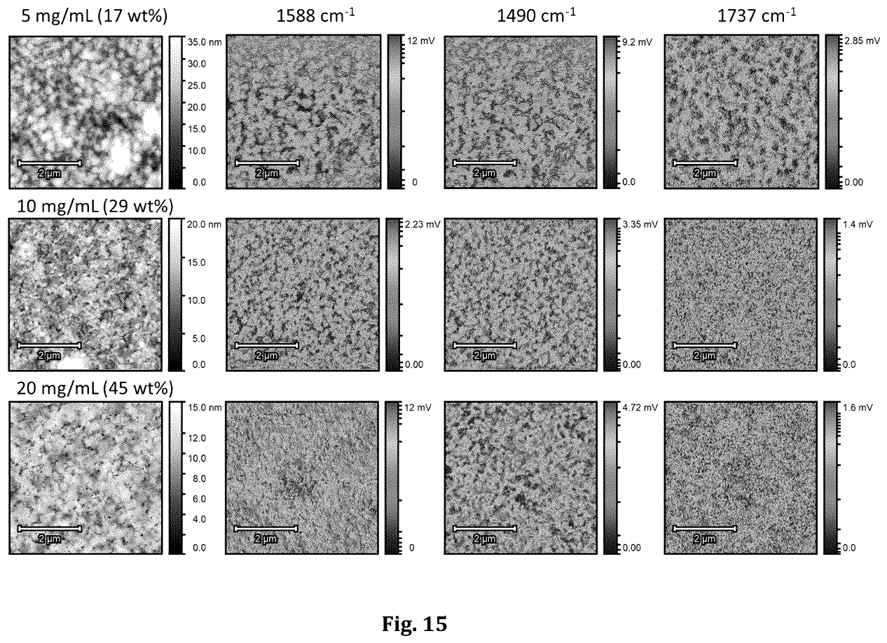

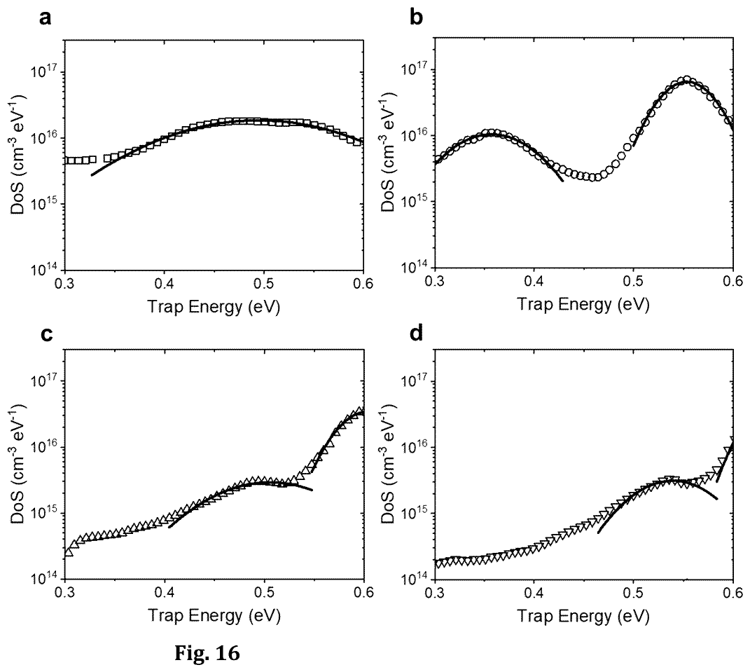

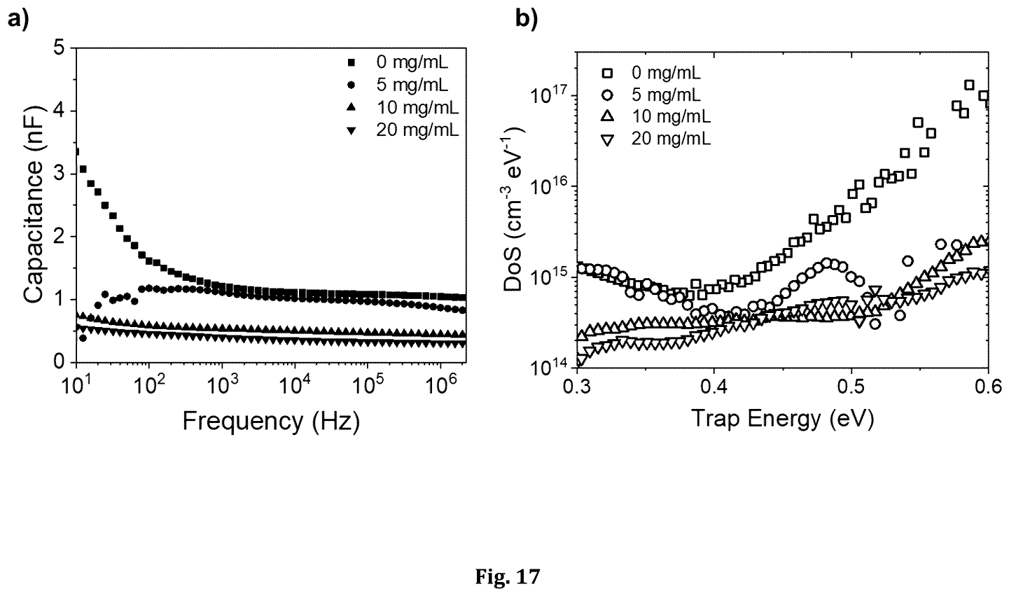

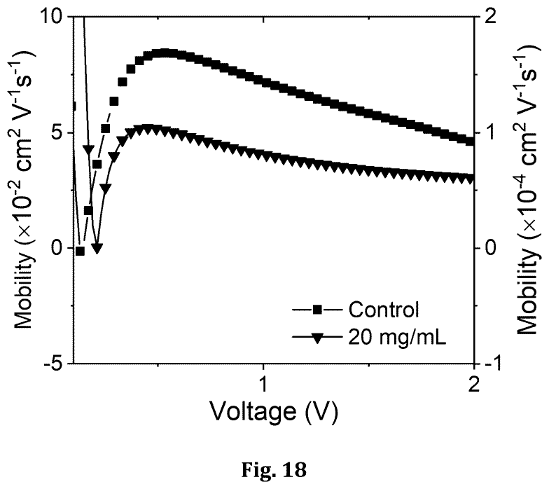

In the case of BHJs, the addition of an inert component required that the donor and acceptor components be sufficiently mixed to enable efficient exciton dissociation and charge separation. Each functional species must also form a percolating structure in order to allow efficient charge transport for electrons and holes to their respective electrodes. Atomic force microscopy (AFM) images of BHJ films incorporating PSU films demonstrated that PSU was mixed throughout the bulk in the composite films, diluting the active semiconductor components, progressing from 5 mg/mL to 20 mg/mL (FIGS. 9, 15D). Without the addition of PSU, the CDT-TQ:PC₇₁BM film exhibited a smooth film with a root-mean-square (RMS) surface roughness of 1.95 nm. Increasing the concentration increased the RMS to 6.90 nm and decreased again to 1.90 nm (FIG. 10). Additionally, the gradual addition of PSU significantly increased the thickness of the active layer from 180 nm for the control device to 340 nm, 570 nm, and 580 nm at 5, 10, and 20 mg/mL, respectively. The large differences in thickness may contribute to the noise suppression; therefore, the dark current to the electric field was normalized, as shown in FIG. 13.

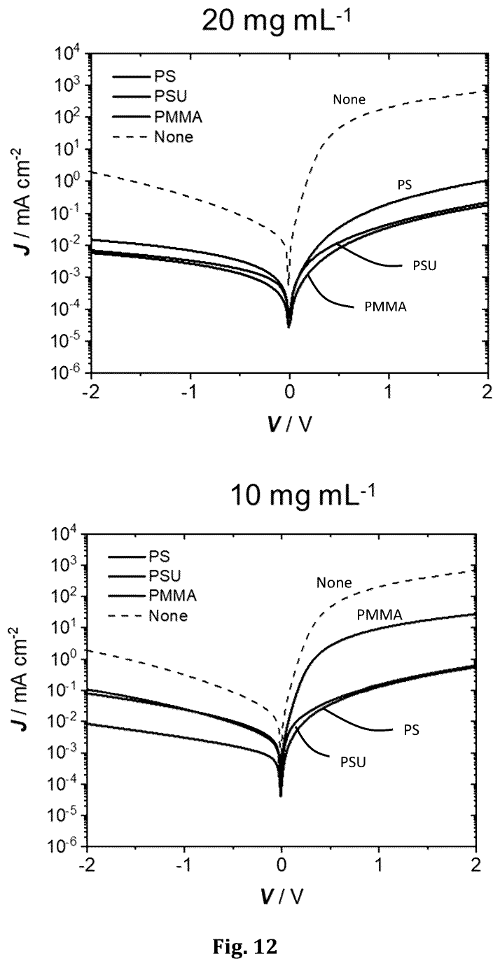

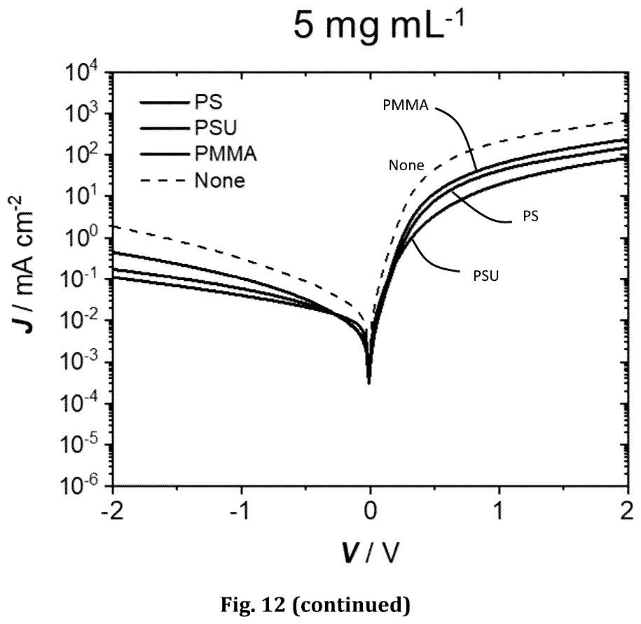

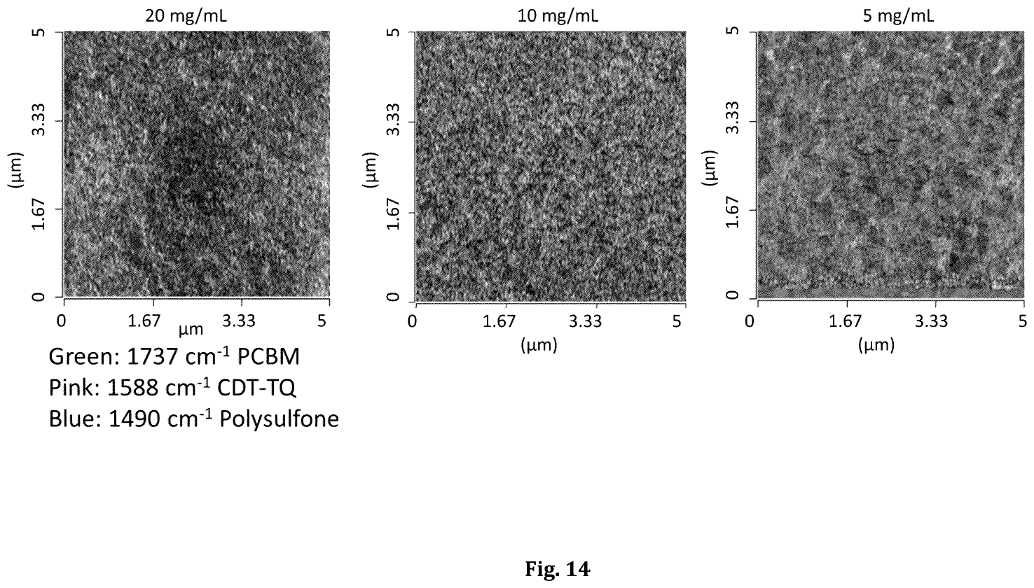

Additional AFM-infrared spectroscopy (AFM-IR) was conducted to better understand the distribution of components within the blends. In the absence of PSU, a prototypical BHJ morphology was evident, with phase separated domains on the order of 120 nm (See FIG. 10 or 12). At 5 mg/mL PSU, large domains (250 nm) were present that contained semiconductors as well as the insulating polymer. The progressive addition of PSU at 10 and 20 mg/mL resulted in more pronounced and finer phase separation of CDT-TQ and PSU, consistent with improved macrophase separation and also finer phase separation of the polymer and PCBM as the concentration was increased. (FIG. 14). The average size of the domains increased from 120 nm to 400 nm, with less pronounced mixing of components.

Trap states (i.e., defect states) with intra-gap energies were prevalent within BHJ OPDs on account of the disordered nature of OSCs, structural defects, varying morphological features, the presence of impurities, and other contributions. These traps act as recombination centers, capture charge carriers, and increase dark current. To further understand the trap distribution/density along with the addition of PSU, capacitance-frequency (C-f) measurements to characterize the density-of-states (DOS) distribution were utilized. In these measurements, an applied ac bias modulated the occupation of defect/trap states near the Fermi energy, enabling a determination of the fraction of trapped charges that are thermally excited to mobile transport states. The trap energy (E_{ω}), corresponds to traps within the bandgap that can respond to ac modulation, and is expressed as a function of the measurement frequency by

$${E}_{ω} = kT ln ( \frac{{ω}_{0}}{ω} ) \qquad ( 3 )$$

where k is Boltzmann's constant, T is the temperature, and ω₀ is the rate prefactor for thermal excitation from the trap and is around 10¹² s−1 in typical OPDs. The trap/defect density of states (DOS) distribution connects the materials composition and electronic properties, specifically to estimate localized trap states and is extracted from the C-f measurement according to the following equation:³⁷⁻³⁹

$$DOS ( {E}_{ω} ) = - \frac{{V}_{bi}}{qAtkT} \frac{dC ( ω )}{d ln ( ω )} \qquad ( 4 )$$

where V_{bi} is the built-in potential, q is the elementary charge, A is the device active area, t is the film thickness, and C(ω) is the capacitance measured with an ac perturbation of angular frequency, ω. Here V_{bi} ranges from 0.17 V to 0.21 V for different PSU concentrations, and the temperature is ˜300 K. It is important to note that the capacitance measurement accounts for the sum of electron and hole traps rather than each component exclusively.

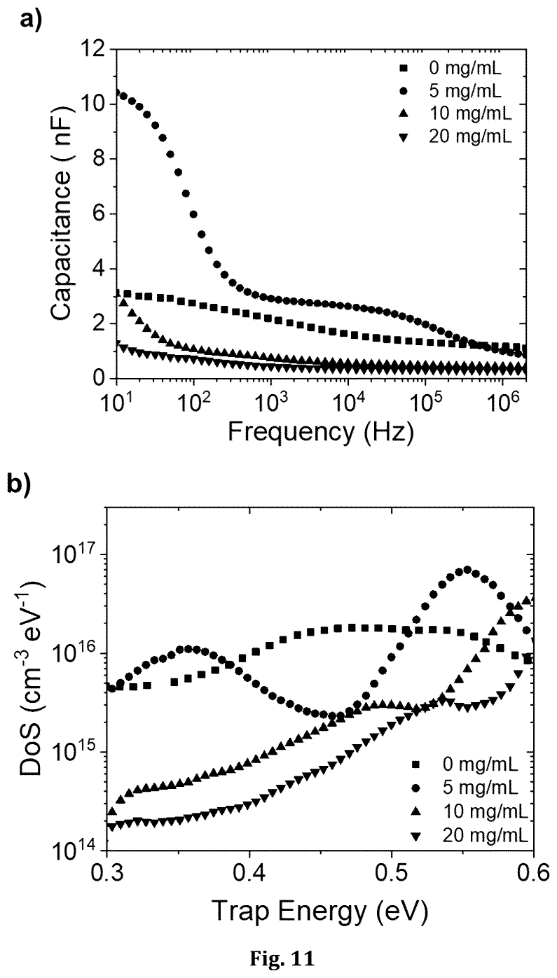

The C-f behavior in the dark at 0 V bias demonstrated a rapid change in slope dC(ω)/(dln(ω)), which reflects an increase of the trap DOS. As shown in the C-f plots in FIG. 11A, it was observed that with increasing concentration of PSU, the DOS near the band-tail (shallow traps from 0.3 eV to 0.45 eV) was reduced when compared to the control device, however, the deep traps remained (peaks in the range of 0.45 eV to 0.6 eV). This was an indication of more shallow traps in the neat blend (FIG. 12). A change of the slope was also observed (dC/dω) of the devices with the progressive addition of PSU in the frequency range from 10²-10³ Hz with an additional transition at 10⁵ Hz for the 5 mg/mL device. This trend indicates the presence of separated groups of shallow and deep traps located at different energy levels. In addition, a reduction of shallow traps at the high frequency region as concentration was increased was observed. To further quantify the deep trap states, DOS was expressed using a single Gaussian distribution:

$$DOS ( {E}_{ω} ) = \frac{{N}_{G}}{σ \sqrt{2 π}} exp [ - \frac{( {E}_{ω} - {E}_{G 0} )}{2 {σ}^{2}} ] \qquad ( 5 )$$

where N_{G} is the fitting yielded the density of deep states, σ is the disorder spread, and E_{G0} is the mean energy of the deep traps. The DOS for different PSU concentrations are depicted in FIG. 12B, and the best-fit values are listed in Table 2. FIG. 12B demonstrates the defect DOS distributions derived from the C-f analysis using Eq. 4. Distinct DOS distributions located at approximately 0.35 eV and 0.55 eV were observed in low concentrations of PSU. When fitted with Eq. 5, N_{G} was reduced when using PSU from 3.97×10¹⁵ cm⁻³ in the control device to 0.31×10¹⁵ cm⁻³ in the 20 mg/mL device at a shallow trap range of 0.3 eV to 0.45 eV. Additionally, a shift in the DOS trap distribution in the high energy region was observed as the concentration of PSU increased. This shift was attributed to a reduction in the shallow traps and into the deep traps that can be caused by a gradual disruption of charge carriers, while maintaining the concentration of traps.

TABLE 2
Parameters obtained from the Gaussian distribution of trap DOS.

| PSU Concentration (mg mL⁻¹) | N_{G} (10¹⁵ cm⁻³) | E_{G0} (eV) | σ (eV) |
|---|---|---|---|
| 0 | 3.97 ± 0.02 | 0.49 | 0.08 |
| 5 (First peak) | 1.03 ± 0.16 | 0.36 | 0.04 |
| 5 (Second peak) | 4.13 ± 0.16 | 0.55 | 0.02 |
| 10 (First peak) | 0.42 ± 0.02 | 0.50 | 0.03 |
| 10 (Second peak) | 2.36 ± 0.05 | 0.60 | 0.03 |
| 20 (First peak) | 0.31 ± 0.02 | 0.54 | 0.04 |
| 20 (Second peak) | 5.77 ± 0.20 | 0.65 | 0.03 |

The Gaussian DOS distribution characterizes the localized, deep trap states in the band gap. Carriers trapped in these deep states are difficult to escape before recombination occurs. Excluding the range below 10 Hz, the decrease of the shallow trap density correlates with the reduction in the dark current at the expense of increasing deep traps which may have been the cause of the reduced EQE. This reduction was also concurrent with the microscopy images of the highest concentration of PSU which formed thick films with large insulator domains that could inhibit the percolation pathway of charge carriers. The decrease in shallow traps was attributed to the dilution of the charge carrier components with an insulator at the ternary blend interface which is consistent with the observation of Abbaszadeh et al.³⁴

### EXAMPLES

The following examples are illustrative, but not limiting, of the methods and compositions of the present disclosure. Other suitable modifications and adaptations of the variety of conditions and parameters normally encountered in the field, and which are obvious to those skilled in the art, are within the spirit and scope of the disclosure. All patents and publications cited herein are fully incorporated by reference herein in their entirety.

### Example 1

This example involved the detailed device fabrication procedure for the polymer-insulator blend using an architecture of ITO/PEDOT:PSS/BHJ (bulk heterojunction)/ZnO/Al. ITO substrates were ultrasonically cleaned in detergent, deionized water, acetone, and 2-propanol for 10 minutes each in sequential cleaning steps. The substrates were dried and treated with UV-ozone for 10 minutes. Poly(3,4-ethylenedioxythiophene) polystyrene sulfonate (PEDOT:PSS) was filtered through a 0.45 μm PTFE syringe filter before spin-coating it onto the dried ITO substrates at 3500 rpm. The coated ITO substrates were then annealed at 120° C. in ambient conditions before transferring them to an N₂-filled glovebox. The photoactive polymer, (poly(4-(5-(4-(3,5-bis(dodecyloxy)benzylidene)-4H-cyclopenta[2,1-b:3,4-b′]dithiophen-2-yl)thiophen-2-yl)-6,7-dioctyl-9-(thiophen-2-yl)-[1,2,5]thiadiazolo[3,4-g]quinoxaline) blended with [6,6]-phenyl-C₇₁-butyric acid methyl ester ([70]PCBM) in a 1:2 weight ratio was dissolved in anhydrous chlorobenzene at a polymer concentration of 7 mg/mL. The insulating component, for example, polysulfone was dissolved in anhydrous chlorobenzene at a concentration of 20 mg/mL and this solution was used to further dissolve the active materials. The blend solutions were spin-coated onto the PEDOT:PSS/ITO substrates at 1000 rpm. After drying, a zinc oxide (ZnO) nanoparticle solution in methanol was spin-coated onto the dried device at 3000 rpm. To complete the fabrication of the device, 100 nm Al electrodes were deposited on top of the blend film by thermal evaporation in a vacuum chamber at a pressure of 1×10⁻⁶ torr. The effective areas of these photodetectors were 4 mm².

### Example 2

This example involved the detailed device fabrication procedure for the polymer-insulator blend using an architecture of ITO/ZnO/BHJ/MoOₓ/Ag. ITO substrates were ultrasonically cleaned in detergent, deionized water, acetone, and 2-propanol for 10 minutes each in sequential steps. The substrates were further dried and treated with UV-ozone for 10 minutes. Zinc oxide nanoparticles were spin coated onto the dried ITO substrates at 3000 rpm and annealed at 150° C. in ambient conditions before transferring them to an N₂-filled glovebox. The photoactive polymer, (poly(4-(5-(4-(3,5-bis(dodecyloxy)benzylidene)-4H-cyclopenta[2,1-b:3,4-b′]dithiophen-2-yl)thiophen-2-yl)-6,7-dioctyl-9-(thiophen-2-yl)-[1,2,5]thiadiazolo[3,4-g]quinoxaline) blended with [70]PCBM in a 1:2 weight ratio was dissolved in anhydrous chlorobenzene at a polymer concentration of 7 mg/mL. The insulating component, for example polysulfone, was dissolved in anhydrous chlorobenzene at a concentration of 20 mg/mL and was used to dissolve the active materials. The blend solutions were spin-coated on the ZnO/ITO substrates at 1000 rpm. To complete the fabrication of the device, 15 nm of MoOₓ, followed by 100 nm Ag, were deposited on top of the blend film by thermal evaporation in a vacuum chamber at a pressure of 1×10⁻⁶ torr. The effective areas of these photodetectors was 4 mm².

### Example 3

This example involved the detailed device fabrication procedure for the polymer-insulator blend with the addition of non-fullerene electron acceptors using an architecture of ITO/ZnO/BHJ/MoOₓ/Ag. ITO substrates were ultrasonically cleaned in detergent, deionized water, acetone, and 2-propanol for 10 minutes each in sequential steps. The ITO substrates were further dried and treated with UV-ozone for 10 minutes. Zinc oxide nanoparticles were spin coated onto the dried ITO substrates at 3000 rpm and annealed at 150° C. in ambient conditions before transferring them to an N₂-filled glovebox. The photoactive polymer, (poly(4-(5-(4-(3,5-bis(dodecyloxy)benzylidene)-4H-cyclopenta[2,1-b:3,4-b′]dithiophen-2-yl)thiophen-2-yl)-6,7-dioctyl-9-(thiophen-2-yl)-[1,2,5]thiadiazolo[3,4-g]quinoxaline) and non-fullerene electron acceptor, 2,2′-((2Z,2′Z)-((12,13-bis(2-ethylhexyl)-3,9-diundecyl-12,13-dihydro-[1,2,5]thiadiazolo[3,4-e]thieno[2″,3″:4′,5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1-diylidene))dimalononitrile (Y6) were employed in a 1:1 weight ratio and dissolved in anhydrous chlorobenzene at a polymer concentration of 7 mg/mL. The insulating component, for example polysulfone, was dissolved in anhydrous chlorobenzene at a concentration of 10 mg/mL and was used to dissolve the active materials. The blend solutions were spin-coated on ZnO/ITO substrates at 2000 rpm. To complete the fabrication of the device, 15 nm of MoOₓ, followed by 100 nm Ag, were deposited on top of the blend film by thermal evaporation in a vacuum chamber at a pressure of 1×10⁻⁶ torr. The effective areas of these photodetectors was 4 mm².

### Example 4

This example involved the detailed device fabrication procedure for the polymer-insulator blend using an architecture of ITO/ZnO/BHJ/MoOₓ/Ag. ITO substrates were ultrasonically cleaned in detergent, deionized water, acetone, and 2-propanol for 10 minutes each in sequential steps. The substrates were further dried and treated with UV-ozone for 10 minutes. A zinc oxide sol gel in 2-methoxyethanol was spin coated onto the dried ITO substrates at 3000 rpm and annealed at 200° C. in ambient conditions before transferring them to an N₂-filled glovebox. The photoactive polymer, (poly(4-(5-(4-(3,5-bis(dodecyloxy)benzylidene)-4H-cyclopenta[2,1-b:3,4-b′]dithiophen-2-yl)thiophen-2-yl)-6,7-dioctyl-9-(thiophen-2-yl)-[1,2,5]thiadiazolo[3,4-g]quinoxaline) blended with [70]PCBM in a 1:2 weight ratio was dissolved in anhydrous chlorobenzene at a polymer concentration of 7 mg mL⁻¹. The insulating component such as poly methyl methacrylate was dissolved in anhydrous chlorobenzene at a concentration of 20 mg mL⁻¹ and was used to dissolve the active materials. The blend solutions were spin-coated on the ZnO/ITO substrates at 1000 rpm. To complete the fabrication of the device, 15 nm of MoOₓ, followed by 100 nm Ag, were deposited on top of the blend film by thermal evaporation in a vacuum chamber at a pressure of 1×10⁻⁶ torr. The effective areas of these photodetectors was 4 mm².

### Example 5

a. Materials

The donor polymer was (poly(4-(5-(4-(3,5-bis(dodecyloxy)benzylidene)-4H-cyclopenta[2,1-b:3,4-b′]dithiophen-2-yl)thiophen-2-yl)-6,7-dioctyl-9-(thiophen-2-yl) [1,2,5]thiadiazolo[3,4-g]quinoxaline) and was synthesized as described previously.^{5, 25} The acceptor was [6,6]-Phenyl-C₇₁-butyric acid methyl ester (PC₇₁BM) which was purchased from Nano-C. Polysulfone (PSU) and the solvents were purchased from Sigma Aldrich and used as received.
b. Sample Preparation

All ternary blends investigated in this example comprised of a 1:2 ratio by weight of donor polymer CDT-TQ and PC₇₁BM, to which varying concentrations of insulator (5 mg mL⁻¹, 10 mg mL⁻¹, 20 mg mL⁻¹) was added by pre-dissolution, followed by removal of the solvent by drying under ambient conditions. The concentration of CDT-TQ was 8 mg mL⁻¹. The % loading of insulator was 17%, 29%, and 45%.
c. Device Fabrication

Glass substrates with indium tin oxide (resistivity ≈20 Ωsq⁻¹) (Ossila Ltd.) were sequentially cleaned via ultrasonication in detergent, deionized water, acetone, and isopropanol for 10 minutes. The substrates were further treated with UV-ozone for 15 minutes. A conventional architecture was adopted for the fabrication of the OPDs. Poly(3,4-ethylenedioxythiophene) polystyrene sulfonate, or PEDOT:PSS (Heraeus 4083) was mixed with isopropanol in a 1:4 volume ratio and was spin-cast onto the clean substrates and annealed at 130° C. for 10 minutes under ambient prior to transfer into an N2 glovebox. The donor CDT-TQ and acceptor PC₇₁BM were dissolved in chlorobenzene solutions of PSU and the ternary blend solutions were spun-cast to form BHJ films with thicknesses ≈180-580 nm, as measured by a stylus profilometer (Bruker Dektak XT). A ZnO nanoparticle solution was cast to form an ≈10 nm film for electron extraction. 100 nm of aluminum top electrodes were deposited through thermal evaporation under vacuum at 1×10⁻⁶ torr. The device's active area was 0.04 cm².
d. Device Characterization

Current density-voltage characteristics were recorded in a nitrogen atmosphere under the dark using a Keithley 2400 source measure unit. EQE measurements were performed using the Bentham PVE300, where the monochromatic light source was modulated at 400 Hz by an optical chopper, and the device photocurrent was amplified through a low-noise preamplifier (SRS 570) and measured with a lock-in amplifier (Bentham 496 DSP). Biased measurements were measured via the front end of the preamp. The noise spectral densities were obtained by measuring the device through a preamplifier connected to the signal analyzer (Keysight N9020B MXA).

Electrochemical impedance spectroscopy was performed with a Gamry Interface 1010E potentiostat in the dark and in the frequency range of 10 Hz to 2 MHz. A small AC voltage of 20 mV was used to maintain linearity of the response and high enough to minimize measurement noise. The DC bias was set at 0 V, −0.5 V, −1 V, and −2 V.

TABLE 3

| PSU Concentration (mg mL⁻¹) | N_{G} (10¹⁵ cm⁻³) | E_{G0} (eV) | σ (eV) |
|---|---|---|---|
| 0 | — | — | — |
| 5 (First peak) | 0.45 | 0.22 | 0.10 |
| 5 (Second peak) | 0.086 | 0.48 | 0.03 |
| 10 (Second peak) | 0.75 | 0.60 | 0.03 |
| 20 (First peak) | 0.12 | 0.52 | 0.08 |
| 20 (Second peak) | 0.16 | 0.61 | 0.05 |

Table 3 shows the parameters obtained from the Gaussian distribution of trap DOS at −2 V. Parameters for the control device were unable to properly fit with equation 5.

The role of dark current noise was suppressed and achieved increased detectivity with the application of a reverse bias in the IR OPD' s of the present invention. A systematic change was observed in the photocurrent and dark noise as the concentration of insulating polymer was increased. These modifications provided improved results as the measured noise current from the device was suppressed under reverse bias. The insulating matrix caused a disruption of the charge carriers in the blends affecting the total photocurrent while suppressing noise. Although the overall noise was suppressed, some undesirable trade-offs involved lower shallow trap state density and slower charge carrier mobility as a result of increased film thickness due to a higher solution viscosity. Therefore, polymer insulated-modified devices based on narrow bandgap IR conjugated polymers exhibit increased detectivity despite a decrease in photocurrent signal. The present invention demonstrated that an insulating polymer can alleviate the long standing problems of current narrow band gap systems, which suffer from increased noise carriers.

Other embodiments of the present disclosure will be apparent to those skilled in the art from consideration of the specification and practice of the embodiments disclosed herein. As used throughout the specification and claims, “a” and/or “an” and/or “the” may refer to one or more than one. Unless otherwise indicated, all numbers expressing quantities, proportions, percentages, or other numerical values are to be understood as being modified in all instances by the term “about.” Accordingly, unless indicated to the contrary, the numerical parameters set forth in the specification and claims are approximations that can vary depending upon the desired properties sought to be obtained by the present disclosure. At the very least, and not as an attempt to limit the application of the doctrine of equivalents to the scope of the claims, each numerical parameter should at least be construed in light of the number of reported significant digits and by applying ordinary rounding techniques.

It is to be understood that each component, compound, substituent or parameter disclosed herein is to be interpreted as being disclosed for use alone or in combination with one or more of each and every other component, compound, substituent or parameter disclosed herein.

It is further understood that each range disclosed herein is to be interpreted as a disclosure of each specific value within the disclosed range that has the same number of significant digits. Thus, for example, a range from 1-4 is to be interpreted as an express disclosure of the values 1, 2, 3 and 4 as well as any range of such values.

It is further understood that each lower limit of each range disclosed herein is to be interpreted as disclosed in combination with each upper limit of each range and each specific value within each range disclosed herein for the same component, compounds, substituent or parameter. Thus, this disclosure to be interpreted as a disclosure of all ranges derived by combining each lower limit of each range with each upper limit of each range or with each specific value within each range, or by combining each upper limit of each range with each specific value within each range. That is, it is also further understood that any range between the endpoint values within the broad range is also discussed herein. Thus, a range from 1 to 4 also means a range from 1 to 3, 1 to 2, 2 to 4, 2 to 3, and so forth.

Furthermore, specific amounts/values of a component, compound, substituent or parameter disclosed in the description or an example is to be interpreted as a disclosure of either a lower or an upper limit of a range and thus can be combined with any other lower or upper limit of a range or specific amount/value for the same component, compound, substituent or parameter disclosed elsewhere in the application to form a range for that component, compound, substituent or parameter.

### REFERENCES

All references cited herein are hereby incorporated by reference in their entirety as if fully set forth herein.
1. Arias, A. C.; MacKenzie, J. D.; McCulloch, I.; Rivnay, J.; Salleo, A., Materials and Applications for Large Area Electronics: Solution-Based Approaches. Chem. Rev. 2010, 110 (1), 3-24.
2. Chen, S.; Deng, L.; Xie, J.; Peng, L.; Xie, L.; Fan, Q.; Huang, W., Recent developments in top-emitting organic light-emitting diodes. Adv. Mater. 2010, 22 (46), 5227-39.
3. Gelinck, G.; Heremans, P.; Nomoto, K.; Anthopoulos, T. D., Organic transistors in optical displays and microelectronic applications. Adv. Mater. 2010, 22 (34), 3778-98.
4. Baran, D.; Balan, A.; Celebi, S.; Meana Esteban, B.; Neugebauer, H.; Sariciftci, N. S.; Toppare, L., Processable Multipurpose Conjugated Polymer for Electrochromic and Photovoltaic Applications. Chemistry of Materials 2010, 22 (9), 2978-2987.
5. Krebs, F. C., Fabrication and processing of polymer solar cells: A review of printing and coating techniques. Sol. Energy Mater. Sol. Cells 2009, 93 (4), 394-412.
6. Geffroy, B.; le Roy, P.; Prat, C., Organic light-emitting diode (OLED) technology: materials, devices and display technologies. Polym. Int. 2006, 55 (6), 572-582.
7. Guo, Y.; Yu, G.; Liu, Y., Functional organic field-effect transistors. Adv. Mater. 2010, 22 (40), 4427-47.
8. Usta, H.; Facchetti, A.; Marks, T. J., n-Channel Semiconductor Materials Design for Organic Complementary Circuits. Acc. Chem. Res. 2011, 44 (7), 501-510.
9. Dong, H.; Zhu, H.; Meng, Q.; Gong, X.; Hu, W., Organic photoresponse materials and devices. Chem. Soc. Rev. 2012, 41 (5), 1754-808.
10. Li, G.; Zhu, R.; Yang, Y., Polymer solar cells. Nat Photon 2012, 6 (3), 153-161.
11. Nelson, J., Polymer:fullerene bulk heterojunction solar cells. Mater. Today 2011, 14 (10), 462-470.
12. He, F.; Yu, L., How Far Can Polymer Solar Cells Go? In Need of a Synergistic Approach. The journal of physical chemistry letters 2011, 2 (24), 3102-3113.
13. Azzellino, G.; Grimoldi, A.; Binda, M.; Caironi, M.; Natali, D.; Sampietro, M., Fully inkjet-printed organic photodetectors with high quantum yield. Adv. Mater. 2013, 25 (47), 6829-33.
14. Baeg, K. J.; Binda, M.; Natali, D.; Caironi, M.; Noh, Y. Y., Organic light detectors: photodiodes and phototransistors. Adv. Mater. 2013, 25 (31), 4267-95.
15. Wu, Z.; Zhai, Y.; Kim, H.; Azoulay, J. D.; Ng, T. N., Emerging Design and Characterization Guidelines for Polymer-Based Infrared Photodetectors. Accounts of Chemical Research 2018, 51 (12), 3144-3153.
16. Rogalski, A., Next decade in infrared detectors. SPIE: 2017; Vol. 10433.
17. Dou, L.; Liu, Y.; Hong, Z.; Li, G.; Yang, Y., Low-Bandgap Near-IR Conjugated Polymers/Molecules for Organic Electronics. Chemical Reviews 2015, 115 (23), 12633-12665.
18. Wu, Z.; Zhai, Y.; Kim, H.; Azoulay, J. D.; Ng, T. N., Emerging Design and Characterization Guidelines for Polymer-Based Infrared Photodetectors. Accounts of Chemical Research 2018, 51 (12), 3144-3153.
19. Li, N.; Mahalingavelar, P.; Vella, J. H.; Leem, D.-S.; Azoulay, J. D.; Ng, T. N., Solution-processable infrared photodetectors: Materials, device physics, and applications. Materials Science and Engineering: R: Reports 2021, 146, 100643.
20. Wu, Z.; Yao, W.; London, A. E.; Azoulay, J. D.; Ng, T. N., Elucidating the Detectivity Limits in Shortwave Infrared Organic Photodiodes. Advanced Functional Materials 2018, 28 (18), 1800391.
21. Kublitski, J.; Hofacker, A.; Boroujeni, B. K.; Benduhn, J.; Nikolis, V. C.; Kaiser, C.; Spoltore, D.; Kleemann, H.; Fischer, A.; Ellinger, F.; Vandewal, K.; Leo, K., Reverse dark current in organic photodetectors and the major role of traps as source of noise. Nature Communications 2021, 12 (1), 551.
22. Yang, W.; Qiu, W.; Georgitzikis, E.; Simoen, E.; Serron, J.; Lee, J.; Lieberman, I.; Cheyns, D.; Malinowski, P.; Genoe, J.; Chen, H.; Heremans, P., Mitigating Dark Current for High-Performance Near-Infrared Organic Photodiodes via Charge Blocking and Defect Passivation. ACS Applied Materials & Interfaces 2021, 13 (14), 16766-16774.
23. Wu, Z.; Li, N.; Eedugurala, N.; Azoulay, J. D.; Leem, D.-S.; Ng, T. N., Noise and detectivity limits in organic shortwave infrared photodiodes with low disorder. npj Flexible Electronics 2020, 4 (1), 6.
24. Ferenczi, T. A. M.; Muller, C.; Bradley, D. D. C.; Smith, P.; Nelson, J.; Stingelin, N., Organic Semiconductor:Insulator Polymer Ternary Blends for Photovoltaics. Advanced Materials 2011, 23 (35), 4093-4097.
25. Madec, M.-B.; Crouch, D.; Llorente, G. R.; Whittle, T. J.; Geoghegan, M.; Yeates, S. G., Organic field effect transistors from ambient solution processed low molar mass semiconductor-insulator blends. Journal of Materials Chemistry 2008, 18 (27), 3230-3236.
26. Zhang, Z.; Shi, R.; Amini, A.; So, S. K.; Cheng, C., Organic Semiconductor-Insulator Blends for Organic Field-Effect Transistors. physica status solidi (RRL)—Rapid Research Letters 2022, 16 (5), 2100602.
27. Scaccabarozzi, A. D.; Stingelin, N., Semiconducting:insulating polymer blends for optoelectronic applications—a review of recent advances. Journal of Materials Chemistry A 2014, 2 (28), 10818-10824.
28. Wang, M.; Liu, S.; You, P.; Wang, N.; Tang, G.; Miao, Q.; Yan, F., Insulating Polymers for Enhancing the Efficiency of Nonfullerene Organic Solar Cells. Solar RRL 2020, 4 (6), 2000013.
29. Zeng, H.; Hu, C.; Wu, D.; Xia, J., Boosting the Photovoltaic Performance and Thermal Stability of Organic Solar Cells via an Insulating Fluoropolymer Additive. ChemPlusChem 2022, n/a (n/a), e202200045.
30. Strobel, N.; Eckstein, R.; Lehr, J.; Lemmer, U.; Hernandez-Sosa, G., Semiconductor:Insulator Blends for Speed Enhancement in Organic Photodiodes. Advanced Electronic Materials 2018, 4 (10), 1700345.
31. Shafique, U.; Santato, C.; Karim, K. S., Lateral Organic Semiconductor Photodetector. Part I: Use of an Insulating Layer for Low Dark Current. IEEE Transactions on Electron Devices 2014, 61 (10), 3465-3471.
32. Yao, W.; Wu, Z.; Huang, E.; Huang, L.; London, A. E.; Liu, Z.; Azoulay, J. D.; Ng, T. N., Organic Bulk Heterojunction Infrared Photodiodes for Imaging Out to 1300 nm. ACS Applied Electronic Materials 2019, 1 (5), 660-666.
33. Go, E.; Jin, H.; Yoon, S.; Park, S.; Park, S. H.; Yu, H.; Son, H. J., Unraveling the Origin of Dark Current in Organic Bulk Heterojunction Photodiodes for Achieving High Near-Infrared Detectivity. ACS Photonics 2022, 9 (6), 2056-2065.
34. Abbaszadeh, D.; Kunz, A.; Wetzelaer, G. A. H.; Michels, J. J.; Craciun, N. I.; Koynov, K.; Lieberwirth, I.; Blom, P. W. M., Elimination of charge carrier trapping in diluted semiconductors. Nature Materials 2016, 15 (6), 628-633.
35. Wang, C.; Liu, X.; Xiao, Y.; Bergqvist, J.; Lu, X.; Gao, F.; Fahlman, M., Diluted Organic Semiconductors in Photovoltaics. Solar RRL 2020, 4 (9), 2000261.
36. Manion, J. G.; Gao, D.; Brodersen, P. M.; Seferos, D. S., Insulating polymer additives in small molecule and polymer photovoltaics: how they are tolerated and their use as potential interlayers. Journal of Materials Chemistry C 2017, 5 (13), 3315-3322.
37. MacKenzie, R. C. I.; Shuttle, C. G.; Dibb, G. F.; Treat, N.; von Hauff, E.; Robb, M. J.; Hawker, C. J.; Chabinyc, M. L.; Nelson, J., Interpreting the Density of States Extracted from Organic Solar Cells Using Transient Photocurrent Measurements. The Journal of Physical Chemistry C 2013, 117 (24), 12407-12414.
38. Street, R. A.; Hawks, S. A.; Khlyabich, P. P.; Li, G.; Schwartz, B. J.; Thompson, B. C.; Yang, Y., Electronic Structure and Transition Energies in Polymer—Fullerene Bulk Heterojunctions. The Journal of Physical Chemistry C 2014, 118 (38), 21873-21883.
39. Street, R. A.; Yang, Y.; Thompson, B. C.; McCulloch, I., Capacitance Spectroscopy of Light Induced Trap States in Organic Solar Cells. The Journal of Physical Chemistry C 2016, 120 (39), 22169-22178.
40. London, A. E.; Huang, L.; Zhang, B. A.; Oviedo, M. B.; Tropp, J.; Yao, W.; Wu, Z.; Wong, B. M.; Ng, T. N.; Azoulay, J. D., Donor-acceptor polymers with tunable infrared photoresponse. Polymer Chemistry 2017, 8 (19), 2922-2930.

What is claimed is:

1. A photodetector configured for converting light to an electronic signal, comprising:
a substrate comprising a hole transport component and electron transport component;
one or more photoactive layers each comprising:
one or more semiconducting materials that comprise a photoactive small molecule, oligomeric, or polymeric electron donor and an electron acceptor, wherein the electron donor has a narrow bandgap of less than 1.4 eV; and
one or more insulating materials, wherein the one or more semiconducting materials and the one or more insulating materials are present in a weight ratio of 1:0.1 to about 1:100;
a cathode in electrical contact with the electron or hole transport component; and
an anode in electrical contact with the hole or electron transport component.

2. The photodetector of claim 1, wherein the photoactive polymer electron donor comprises a polymer according to Formula I or Formula II: 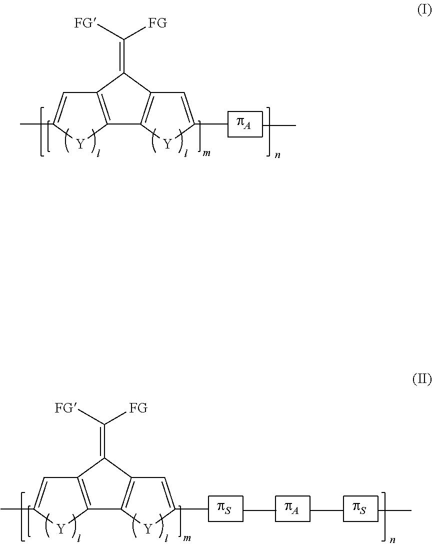
wherein FG and FG′ are each independently selected from the group consisting of hydrogen, an optionally substituted hydrocarbyl group containing 1 to 26 carbon atoms, an optionally substituted aryl group containing 6 to 20 carbon atoms, an optionally substituted heteroaryl group containing 3 to 26 carbon atoms, and an optionally substituted aryl group containing 3 to 26 carbon atoms,
the optionally substituted aryl group is selected from the group consisting of an arylene group substituted with an alkoxy group containing from 1 to 26 carbon atoms, an alkyl group containing from 1 to 26 carbon atoms, and an alkenyl group containing from 1 to 26 carbon atoms,
m is an integer of at least 1, and n is an integer of greater than 1;
Y is selected from the group consisting of S, BR⁵, PR⁵, Se, Te, NH, and Si,
R⁵ is a C₁-C₂₄ hydrocarbyl group;
π_{S} is a conjugated spacer unit comprising a heteroarylene, wherein the heteroarylene has 3 to 6 carbon atoms, and the heteroatom of the heteroarylene is selected from the group consisting of S, O, Se, and N, or the heteroarylene has a structure: 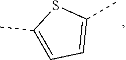
wherein π_{A} is an electron-poor or electron-deficient aromatic moiety that provides a structural unit in the copolymer selected from the group consisting of structural units according to formulae (A)-(F): 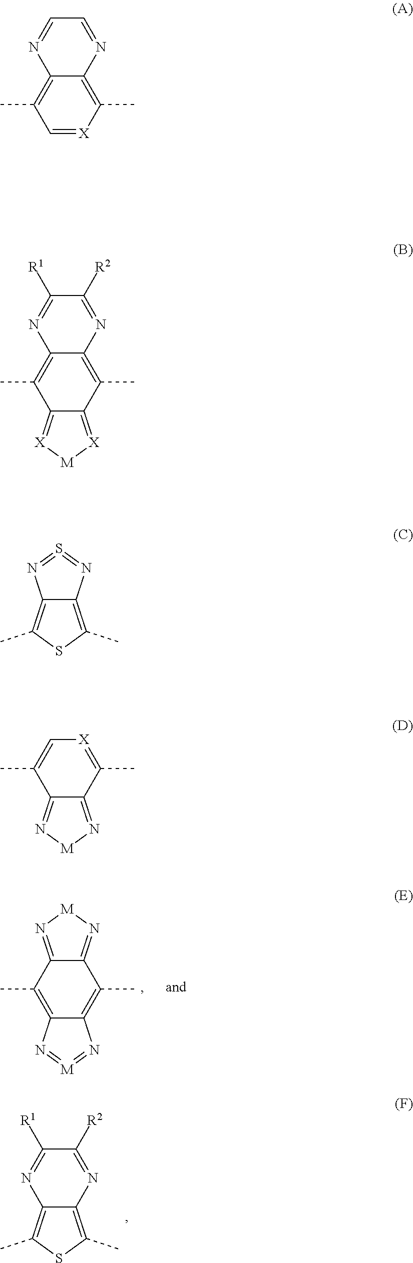
wherein R¹ and R² are each individually selected from the group consisting of a hydrogen, a hydrocarbyl group containing 1 to 26 carbon atoms, an alkoxyl group containing 1 to 26 carbon atoms, an optionally substituted aryl group containing 6 to 20 carbon atoms, and a heteroaryl group containing 3 to 26 carbon atoms,
M, R³, and R⁴ are each independently selected from the group consisting of O, S, and Se, and
X is selected from the group consisting of C and N.

3. The photodetector of claim 1, wherein the hole transport component comprises one or more conducting materials with a work function ranging between 4.5-5.5 eV.

4. The photodetector of claim 1, wherein the electron acceptor comprises one or more of fullerenes, non-fullerene acceptors (NFAs) and polymers.

5. The photodetector of claim 1, wherein the electron acceptor is selected from the group consisting of [6,6]-phenyl-C₇₁-butyric acid methyl ester ([70]PCBM), [60]PCBM, PCBM, C₆₀, C₇₀, fullerenes, 3,4,9,10-perylenetetracarboxylic dianhydride (PTCDA), 2,2′-((2Z,2′Z)-((12,13-bis(2-ethylhexyl)-3,9-diundecyl-12,13-dihydro-[1,2,5]thiadiazolo[3,4-e]thieno[2″,3″:4′,5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1-diylidene))dimalononitrile (BTP-4F), and combinations thereof.

6. The photodetector of claim 1, wherein the photodetector is configured to detect radiation spanning the visible and infrared regions.

7. The photodetector of claim 1, wherein the one or more insulating materials are integrated within the organic photoactive layer.

8. The photodetector of claim 1, wherein the one or more insulating materials comprise an insulating polymer.

9. The photodetector of claim 1, wherein the one or more insulating materials are selected from the group consisting of polyethylene, polystyrene, polysulfone, polymethyl(methacrylate), polycarbonate, polyisobutylene, polylactic acid, polyvinylchloride, polyvinylpyrrolidone, polypropylene, polyethylene terephthalate and acrylonitrile butadiene styrene.

10. A photodetector configured for converting light to an electronic signal, comprising:
a substrate comprising a hole transport component or an electron transport component;
one or more photoactive layers comprising:
a heterojunction of two or more semiconducting materials that comprise a photoactive small molecule, oligomeric, or polymeric electron acceptor and an electron donor present in a weight ratio of from about 1:0.1 to about 1:100, wherein the electron donor has a narrow bandgap of less than 1.4 eV, and
one or more insulating materials, wherein the two or more semiconducting materials and the one or more insulating materials are present in a weight ratio of 1:0.1 to about 1:100;
a cathode in electrical contact with the bulk heterojunction; and;
an anode in electrical contact with the bulk heterojunction.

11. The photodetector of claim 10, wherein the one or more insulating materials are located within the heterojunction or the one or more photoactive layers.

12. The photodetector of claim 10, wherein at least one electrode comprises one or more transparent conducting oxides selected from the group consisting of indium tin oxide (ITO), tin oxide (TO), gallium indium tin oxide (GaITO), and zinc indium tin oxide (ZITO); thin metal layers having a thickness of 50-300 nm; transparent conducting polymers selected from the group consisting of poly(3,4,-ethylenedioxythiophene), (PEDOT), poly(3,4-ethylenedioxythiophene):polystyrene sulfonate (PEDOT:PSS), polyaniline, and polypyrrole, or an electrically conductive material.

13. The photodetector of claim 10, wherein said optoelectronic device is configured to generate an electrical current with reduced noise by at least an order of magnitude under bias up to ±5V in response to incident radiation relative to an optoelectronic device in the absence of the narrow bandgap electron donor.

14. A method for producing the photodetector of claim 1 comprising steps of:
mixing one or more photoactive material electron donors with an electron acceptor and one or more insulating materials in a solvent to form a bulk heterojunction;
depositing a film of the bulk heterojunction onto a substrate; and
depositing a cathode and an anode onto the bulk heterojunction to form the photodetector.

15. The method of claim 14, wherein the bulk heterojunction is deposited via a method selected from the group consisting of spin coating, spray coating, blade coating, dip coating, screen printing, flexographic printing, slit coating, and ink-jet printing.

16. The method of claim 14, wherein a first electrode is deposited onto the film of the bulk heterojunction via thermal evaporation in a vacuum chamber at a pressure of about 1×10⁻⁶.

17. The method of claim 16, wherein in the photodetector, a combination of the one or more photoactive polymeric electron donors and the electron acceptor is present in the bulk heterojunction at a concentration of from about 5 mg/ml to about 10 mg/ml.

18. The method of claim 16, wherein in the photodetector, the one or more insulating materials are present in the bulk heterojunction at a concentration of from about 7 mg/ml to about 30 mg/ml.

19. A composition comprising an electron donor, an electron acceptor, and an insulating polymer, wherein the electron donor comprises a polymer according to Formula I or Formula II: 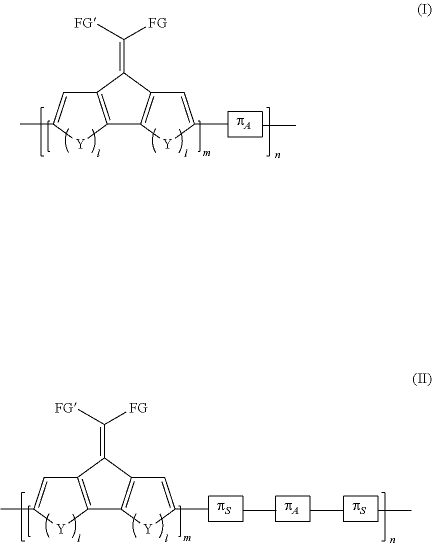
wherein FG and FG′ are each independently selected from the group consisting of hydrogen, an optionally substituted hydrocarbyl group containing 1 to 26 carbon atoms, an optionally substituted aryl group containing 6 to 20 carbon atoms, an optionally substituted heteroaryl group containing 3 to 26 carbon atoms, and an optionally substituted aryl group containing 3 to 26 carbon atoms,
the optionally substituted aryl group is selected from the group consisting of an arylene group substituted with an alkoxy group containing from 1 to 26 carbon atoms, an alkyl group containing from 1 to 26 carbon atoms, and an alkenyl group containing from 1 to 26 carbon atoms,
m is an integer of at least 1, and n is an integer of greater than 1;
Y is selected from the group consisting of S, BR⁵, PR⁵, Se, Te, NH, and Si,
R⁵ is a C₁-C₂₄ hydrocarbyl group;
π_{S} is a conjugated spacer unit comprising a heteroarylene, wherein the heteroarylene contains 3 to 6 carbon atoms, and wherein the heteroatom of the heteroarylene is selected from the group consisting of S, O, Se, and N, or the heteroarylene has a structure: 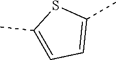
π_{A} is an electron-poor or electron-deficient aromatic moiety that provides a structural unit in the copolymer selected from the group consisting of a structural unit of formulae (A)-(F): 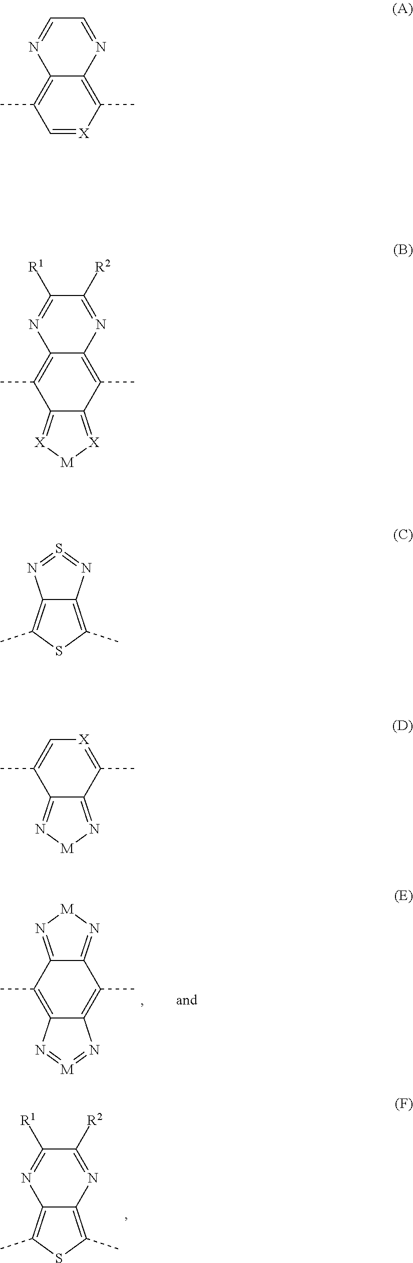
R¹ and R² are each individually selected from a hydrogen, a hydrocarbyl group containing 1 to 26 carbon atoms, an alkoxyl group containing 1 to 26 carbon atoms, an optionally substituted aryl group containing 6 to 20 carbon atoms, and a heteroaryl group containing 3 to 26 carbon atoms,
M, R³, and R⁴ are each independently selected from the group consisting of O, S, and Se, and
X is selected from the group consisting of C and N.

20. A method for producing the photodetector of claim 10 comprising steps of:
mixing one or more photoactive material electron donors with an electron acceptor and one or more insulating materials in a solvent to form a bulk heterojunction;
depositing a film of the bulk heterojunction onto a substrate; and
depositing a cathode and an anode onto the bulk heterojunction to form the photodetector.
